(19) United States
(12) Patent Application Publication
(10) Pub. No.: US 2007/0166647 A1
(43) Pub. Date: Jul. 19, 2007

(54) Light sensitive planographic printing plate material and planographic printing plate manufacturing process

(75) Inventor: Takaaki Kuroki, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KONICA MINOLTA MEDICAL & GRAPHIC, INC.

(21) Appl. No.: 11/652,491

(22) Filed: Jan. 12, 2007

(30) Foreign Application Priority Data
Jan. 17, 2006 (JP) JP2006-008540

(51) Int. Cl. G03F 7/00

(52) U.S. Cl. 430/302

(57) ABSTRACT

Disclosed is a light sensitive planographic printing plate material comprising a support and provided thereon, a light sensitive layer containing a polymeric binder, a polymerizable ethylenically unsaturated compound and a photopolymerization initiator, wherein the polymeric binder is a polymer having a acid value of from 40 to 120 and a glass transition temperature Tg of from 105 to 200 ° C.

This application is based on Japanese Patent Application No. 2006-008540, filed on Jan. 17, 2006 in Japanese Patent Office, the entire content of which is hereby incorporated by reference.

### FIELD OF THE INVENTION

The present invention relates to a negative working light sensitive planographic printing plate material for so-called a computer-to-plate system (hereinafter referred to as CTP system), and particularly to a light sensitive planographic printing plate material suitable for exposure employing laser emitting light with an emission wavelength of from 350 to 430 nm and a process of manufacturing a planographic printing plate therefrom.

### BACKGROUND OF THE INVENTION

Presently, digital technique electronically processing, storing and outputting image information employing a computer has spread. In a plate making system of a planographic printing plate for off-set printing, a CTP system, which writes a digital image directly on a light sensitive planographic printing plate material employing a laser, has been developed and put into practical use.

It is known that of the light sensitive planographic printing plate materials used for CTP, a negative working light sensitive planographic printing plate material comprising a polymerizable light sensitive layer containing a polymerizable compound is used in a printing field in which relatively high printing durability is required (see for example, Japanese Patent O.P.I. Publication Nos. 1-105238 and 2-127404.). Such a negative working light sensitive planographic printing plate material usually comprises a light sensitive layer containing a polymeric binder, an ethylenically unsaturated compound and a polymerization initiator.

As a polymeric binder used in a polymerizable light sensitive layer have been used alkali-soluble organic polymers such as a methacrylic acid copolymer, acrylic acid copolymer, itaconic acid copolymer, crotonic acid copolymer, maleic acid copolymer and partially esterified maleic acid copolymer, as disclosed in Japanese Patent O.P.I. Publication No. 59-44615, Japanese Patent Publication Nos. 54-34327, 58-12577, and 54-25957, and Japanese Patent O.P.I. Publication Nos. Nos. 54-92723, 59-53836 and 59-71048.

Such a conventional negative working light sensitive planographic printing plate material comprising conventional polymeric binders described above has problems in that sensitivity to the wavelength of laser light and printing durability are insufficient. For example, when an exposure scanning speed is increased in order to increase productivity, exposure energy per unit area of the light sensitive layer surface of the planographic printing plate material is small, resulting in an insufficiently hardened light sensitive layer at exposed portions, which is susceptible to damage by alkali components in a developer.

It is well known that high sensitivity and high printing durability are obtained by heating such a negative working light sensitive planographic printing plate material comprising a photopolymerizable light sensitive layer during exposure or before or after exposure. In the. photopolymerization type light sensitive planographic printing plate material, heating after exposure is mainly carried out at present.

Such a heating can increase printing durability of a printing plate, however, too much heating has problems in that it causes decomposition of photopolymerization initiators or undesired polymerization reaction of ethylenically unsaturated compounds, resulting in occurrence of fog. Therefore, the heating temperature has an upper limitation, which is generally up to maximum of about 100° C.

As countermeasures for solving the above problems, an acid value or glass transition temperature of polymeric binders has been studied (see Japanese Patent O.P.I. Publication Nos. 2004-219667 and 2001-100408.). For example, use of a polymeric binder having an acid value of from 0.7 to 2 and a glass transition temperature of not more than 120° C. is disclosed in Japanese Patent O.P.I. Publication No. 2004-219667. In this technique, printing durability and developability are somewhat improved, however, sensitivity, storage stability and anti-stain property, as well as printing durability and developability, do not still arrive at the levels required by users.

### SUMMARY OF THE INVENTION

In view of the above, the present invention has been made. An object of the invention of the invention is to provide a light sensitive light sensitive planographic printing plate material having excellent sensitivity, storage stability, anti-stain property and printing durability, and to provide a manufacturing process of a planographic printing plate from the light sensitive planographic printing plate material.

### DETAILED DESCRIPTION OF THE INVENTION

The above object of the invention can be attained by any one of the following constitutions.

1. A light sensitive planographic printing plate material comprising a support and provided thereon, a light sensitive layer containing a polymeric binder, a polymerizable ethylenically unsaturated compound and a photopolymerization initiator, wherein the polymeric binder is a polymer having an acid value of from 40 to 120 and a glass transition temperature Tg of from 105 to 200° C.

2. The light sensitive planographic printing plate material of item 1 above, wherein said polymer has an acid value of from 60 to 110 and a glass transition temperature Tg of from 110 to 180° C.

3. The light sensitive planographic printing plate material of item 1 or 2, wherein said polymer is a copolymer containing two or more kinds of monomer units, the glass transition temperature of a homopolymer consisting of one of the monomer units constituting the copolymer being not less than 105° C.

4. The light sensitive planographic printing plate material of item 3 above, wherein the copolymer comprises a (meth)acrylic acid-monomer unit in the molecule.

5. The light sensitive planographic printing plate material of any one of items 1 through 4 above, wherein the polymerizable ethylenically unsaturated compound has both amide bond and a secondary or tertiary amino group in the molecule.

6. The light sensitive planographic printing plate material of any one of items 1 through 5 above, wherein the photopolymerization initiator is selected from the group consisting of a polyhalogenated compound, a biimidazole compound and an iron arene complex.

7. The light sensitive planographic printing plate material of item 6 above, wherein the photopolymerization initiator is a combination of a polyhalogenated compound and an iron arene complex.

8. The light sensitive planographic printing plate material of item 1 above, wherein the content of the polymeric binder in the light sensitive layer is from 10 to 90% by weight, based on the total weight of the light sensitive layer, the content of the polymerizable ethylenically unsaturated compound in the light sensitive layer is from 1.0 to 80% by weight, based on the total weight of the light sensitive layer, and the content of the photopolymerization initiator in the light sensitive layer is from 0.1 to 20% by weight, based on the weight of the polymerizable ethylenically unsaturated compound contained in the light sensitive layer.

9. The light sensitive planographic printing plate material of item 8 above, wherein the content ratio by weight of the polymerizable ethylenically unsaturated compound to the polymeric binder in the light sensitive layer is from 0.5 to 2.2.

10. The light sensitive planographic printing plate material of any one of items 1 through 9 above, wherein the light sensitive layer further contains an organic amine.

11. The light sensitive planographic printing plate material of item 10 above, wherein the organic amine content of the light sensitive layer is from 0.1 to 20% by weight.

12. The light sensitive planographic printing plate material of item 10 above, wherein the organic amine is represented by formula (I),

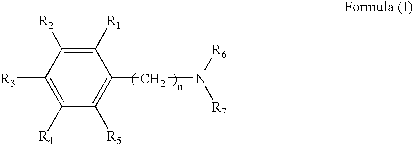

wherein n represents an integer of from 1 to 10; R₁ through R₅ independently represent a hydrogen atom, a halogen atom, a hydroxyl group, a formyl group, a carboxyl group, a cyano group, a nitro group, a sulfo group, a substituted or unsubstituted alkyl group, a substituted or unsubstituted alkenyl group, a substituted or unsubstituted aryl group, a substituted or unsubstituted aromatic heterocyclic group, a substituted or unsubstituted alkoxy group, a substituted or unsubstituted aryloxy group, a substituted or unsubstituted acyl group, a substituted or unsubstituted alkoxycarbonyl group, a substituted or unsubstituted acryloyloxy group, a substituted or unsubstituted alkylcarbonyloxy group, a substituted or unsubstituted alkylthio group, a substituted or unsubstituted sulfonyl group, a substituted or unsubstituted arylthio group, a substituted or unsubstituted amino group or a substituted or unsubstituted amido group; and R₆ and R₇ independently represent a hydrogen atom, a substituted or unsubstituted alkyl group, a substituted or unsubstituted alkenyl group, a substituted or unsubstituted aryl group, a substituted or unsubstituted aromatic heterocyclic group, or a substituted or unsubstituted aryloxy group.

13. A process for manufacturing a planographic printing plate from the light sensitive planographic printing plate material of any one of items 1 through 10 above, the process comprising the steps of (a) imagewise exposing the light sensitive planographic printing plate material, (b) pre-heating the resulting imagewise exposed planographic printing plate material at a temperature of less than Tg of the polymeric binder, and (c) developing the pre-heated planographic printing plate material, whereby a planographic printing plate is obtained.

The light sensitive planographic printing plate material of the invention, comprising a support and provided thereon, a light sensitive layer containing a polymeric binder, a polymerizable ethylenically unsaturated compound and a photopolymerization initiator, is characterized in that the light sensitive layer contains, as a polymeric binder, a polymer having an acid value of from 40to 120 and a glass transition temperature Tg of from 105 to 200° C.

The invention will be explained in detail below.

### (Polymeric Binder)

The light sensitive planographic printing plate material of the invention is characterized in that the light sensitive layer contains, as a polymeric binder, a polymer (hereinafter also referred to as the polymer in the invention) having an acid value of from 40 to 120 and a glass transition temperature Tg of from 105 to 200° C.

In the invention, “acid value of polymer” refers to an amount by mg of KOH necessary to neutralize 1 g of the polymer.

The acid value herein referred to is measured according to a method (a titration method) described in JIS K0070-1992. The glass transition temperature (Tg) in the invention refers to a temperature at which two straight lines, obtained when the specific volume of a polymer is plotted against temperature, cross, as defined in,“Kobunshi Kagaku” published in 1993 by Kyoritu Shuppan Co. Glass transition temperature is measured through a differential scanning calorimeter (DSC). The glass transition temperature (Tg) of the polymeric binder in the invention is also measured through the DSC.

The acid value of the polymer in the invention is from 40 to 120, preferably from 60 to 110, and more preferably from 80 to 100. The Tg of the polymer in the invention is from 105 to 200° C., preferably from 110 to 180° C., and more preferably from 115 to 160° C.

The average molecular weight of the polymer in the invention is preferably from 10,000 to 100,000, more preferably from 20,000 to 80,000, and more preferably from 30,000 to 60,000.

In the process of manufacturing a planographic printing plate from a light sensitive planographic printing plate material, when the imagewise exposed light sensitive planographic printing plate material is pre-heated before development, the polymer having a Tg falling within the range described above cures at high speed without softening on heating, providing a cured layer with high strength, and high printing durability.

A layer containing, as a polymeric binder, a polymer with too a high acid value provides good developability, but has high permeability of developer. Such a layer easily swells at image portions during development, resulting in poor printing durability. Therefore, it is necessary in the invention that the acid value of the polymer be in the range described above.

The polymer in the invention is preferably a copolymer containing two or more kinds of (co)monomer units, the glass transition temperature of a homopolymer consisting of one of the (co)monomer units constituting the copolymer being not less than 105° C.

Examples of the (co)monomer, in which a homopolymer formed only from the monomer has a glass transition temperature Tg of not less than 105° C., include (meth)acrylic acid, 1-adamanyl (meth)acrylate, adamanyl crotonate, adamanyl sorbate. 3,5-dimethyladamantyl (meth)acrylate, 3,5-dimethyladamantyl crotonate, ferrocenylethyl (meth)acrylate, ferrocenylmethyl (meth)acrylate, 3-fluoroalkyl-α-fluoro(meth)acrylate, magnesium (meth)acrylate, pentabromobenzyl (meth)acrylate, potassium (meth)acrylate, sodium (meth)acrylate, zinc (meth)acrylate, (meth)acrylamide, N-tert-butyl (meth)acrylamide, N,N-diisopropyl (meth)acrylamide, N-(1-methylbutyl) (meth)acrylamide, N-methyl-N-phenyl (meth)acrylamide, morpholyl (meth)acrylamide, piperidyl (meth)acrylamide, 2-decanehydronaphthyl methacrylate, 3,3-dimethyl-2-butyl methacrylate, isobornyl methacrylate, methyl methacrylate, 4-methoxycarbonylphenyl methacrylate, phenyl methacrylate, 3-tetracyclododecyl methacrylate, 3,3,5-trimethylcyclohexyl methacrylate, 2,3-xylenyl methacrylate, 2,6-xylenyl methacrylate, 4-butoxycarbonylphenyl methacrylamide, 4-carboxyphenyl methacrylamide, cyclohexyl chloroacrylate, methyl chloroacrylate, 4-hydroxystyrene, tert-butylstyrene, 2-carboxystyrene, 2,5-diisopropylstyrene, 2-dimethylaminocarbonylstyrene, 2,5-dimethylstyrene, 2-hydroxystyrene, and 4-phenylstyrene.

In the invention, other polymers described below can be used in addition to the polymer in the invention.

Examples of other polymers include a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These resins can be used as an admixture of two or more thereof.

The polymer in the invention is preferably a copolymer obtained by copolymerization of acryl monomers, more preferably a copolymer containing (i) a carboxyl group-containing monomer unit and (ii) an alkyl methacrylate or alkyl acrylate unit, and still more preferably a copolymer containing a (meth)acrylic acid monomer unit in the molecule.

Examples of the carboxyl group-containing monomer include an α, β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methyl methacrylate, ethyl methacrylate, propyl methacrylate, butyl methacrylate, amyl methacrylate, hexyl methacrylate, heptyl methacrylate, octyl methacrylate, nonyl methacrylate, decyl methacrylate, undecyl methacrylate, dodecyl methacrylate, methyl acrylate, ethyl acrylate, propyl acrylate, butyl acrylate, amyl acrylate, hexyl acrylate, heptyl acrylate, octyl acrylate, nonyl acrylate, decyl acrylate, undecyl acrylate, or dodecyl acrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymer in the invention can further contain, as another comonomer unit, a monomer unit derived from the monomer described in the following items 1) through 14):

1) A monomer having an aromatic hydroxy-group, for example, o-, (p- or m-) hydroxystyrene, or o-, (p- or m-) hydroxyphenylacrylate;

2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

3) A monomer having an aminosulfonyl group, for example, m- or p-aminosulfonylphenyl methacrylate, m- or p-aminosulfonylphenyl acrylate, N-(p-aminosulfonylphenyl) methacrylamide, or N-(p-aminosulfonylphenyl)acrylamide;

4) A monomer having a sulfonamido group, for example, N-(p-toluenesulfonyl)acrylamide, or N-(p-toluenesulfonyl)-methacrylamide;

5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

7) A vinyl ether, for example, ethyl vinyl ether, 2-chloroethyl vinyl ether, propyl vinyl ether, butyl vinyl ether, octyl vinyl ether, or phenyl vinyl ether;

8) A vinyl ester, for example, vinyl acetate, vinyl chroloacetate, vinyl butyrate, or vinyl benzoate;

9) A styrene, for example, styrene, methylstyrene, or chloromethystyrene;

10) A vinyl ketone, for example, methyl vinyl ketone, ethyl vinyl ketone, propyl vinyl ketone, or phenyl vinyl ketone;

11) An olefin, for example, ethylene, propylene, isobutylene, butadiene, or isoprene;

12) N-vinylpyrrolidone, N-vinylcarbazole, or N-vinylpyridine,

13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further still another monomer may be employed as a comonomer.

The above polymers can be manufactured according to a conventional solution polymerization, bulk polymerization or suspension polymerization. A polymerization initiator used is not specifically limited, but examples thereof include azobis type radical generating agents, for example, 2,2′-azobisisobutyrbnitrile (AIBN) or 2,2′-azobis(2-methylbutyronitrile). The amount used of the polymerization initiator is ordinarily from 0.05 to 10.0 part by weight (preferably from 0.1 to 5 part by weight), based on 100 parts by weight of monomer used to prepare a (co)polymer. As the solvents used in the solution polymerization, there are organic solvents including ketones, esters or aromatics, for example, good solvents generally used in the solution polymerization such as toluene, ethyl acetate, benzene, methylcellosolve, ethylcellosolve, acetone, and methyl ethyl ketone. Among these, ones having a boiling point of from 60 to 120° C. are preferred. The solution polymerization is ordinarily carried out at 40 to 120° C. (preferably 60 to 110° C.), for 3 to 10 hours (preferably 5 to 8 hours) employing the above solvents. After completion of polymerization, the solvents are removed from the resulting polymerization solution to obtain a (co)polymer. Alternatively, the polymerization solution is used without removing the solvents in a double bond incorporation reaction as described later which follows.

The molecular weight of the polymer can be adjusted by selecting solvents used or by controlling polymerization temperature. The solvents used or the polymerization temperature for obtaining a polymer with an intended molecular weight is appropriately determined by monomers used. The molecular weight of the polymer can be also adjusted by mixing the above solvents with a specific solvent. Examples of the specific solvent include mercaptans such as n-octylmercaptan, n-dodecylmercaptan, t-dodecylmercaptan and mercaptoethanol, and carbon chlorides such as carbon tetrachloride, butyl chloride and propylene chloride. The mixing ratio of the specific solvent to the solvents described above can be properly determined by monomers used, solvents used or polymerization conditions.

The polymer in the invention is preferably a polymer having, in the side chain, a carboxyl group and a polymerizable double bond. As the polymeric binder is also preferred an unsaturated bond-containing copolymer which is obtained by reacting a copolymer having a carboxyl group in the molecule with for example, a compound having a (meth)acryloyl group and an epoxy group. Examples of the compound having a (meth)acryloyl group and an epoxy group in the molecule include glycidyl acrylate, glycidyl methacrylate and an epoxy group-containing unsaturated compound disclosed in Japanese Patent O.P.I Publication No. 11-27196. Further, an unsaturated bond-containing copolymer is obtained by reacting a copolymer molecule having a hydroxyl group in the molecule with for example, a compound having a (meth)acryloyl group and an isocyanate group. Examples of the compound having a (meth)acryloyl group and an isocyanate group in the molecule include vinyl isocyanate, (meth)acryl isocyanate, 2-(meth)acroyloxyethyl isocyanate, m- or p-isbprbpenyl-α,α′-dimethylbenzyl isocyanate. Among these, (meth)acryl isocyanate or 2-(meth)acroyloxyethyl isocyanate is preferred.

Reaction of a carboxyl group-containing copolymer with a compound having in the molecule a (meth)acryloyl group and an epoxy group can be carried out according to a well-known method. For example, the reaction is carried out at a temperature of 20 to 100° C., and preferably 40 to 80° C., and more preferably at a boiling point of solvent used (while refluxing), for 2 to 10 hours and preferably 3 to 6 hours. As the solvent used in the reaction, there are solvents used in the polymerization to obtain the copolymer described above. After polymerization, the solvent in the polymerization can be used without being removed from the polymerization solution as a reaction solvent used for reaction in which an aliphatic epoxy group-containing unsaturated compound is incorporated into the vinyl copolymer. The reaction can be carried out in the presence of a catalyst or a polymerization inhibitor. As the catalyst, there are amines or ammonium chlorides. Examples of the amines include triethylamine, tributylamine, dimethylaminoethanol, diethylaminoethanol, methylamine, ethylamine, n-propylamine, i-propylamine, 3-methoxypropylamine, butylamine, allylamine, hexylamine, 2-ethylhexylamine, and benzylamine. Examples of the ammonium chlorides include triethylbenzylammonium chloride. The amount used of the catalyst is ordinarily from 0.01 to 20.0% by weight based on the weight of an aliphatic epoxy group-containing unsaturated compound used. Examples of the polymerization inhibitor include hydroquinone, hydroquinone monometyl ether, 2,5-di-t-butylhydroquinone, 2,6-di-t-butylhydroquinone, 2-methylhydroquinone, and 2-t-butylhydroquinone. The amount used of the polymerization inhibitor is ordinarily from 0.01 to 5.0% by weight based on the weight of aliphatic epoxy group-containing unsaturated compound used. The reaction process is controlled by measurement of acid value of the reaction mixture and the reaction is terminated at the time when the intended acid value is attained.

Reaction of a hydroxyl group-containing copolymer with a compound having in the molecule a (meth)acryloyl group and an isocyanate group can be carried out according to a known method. For example, the reaction is carried out at a temperature of 20 to 100° C., and preferably 40 to 80° C., and more preferably at a boiling point of solvent used (while refluxing), for 2 to 10 hours and preferably 3 to 6 hours. As the solvent used in the reaction, there are solvents used in the polymerization to obtain the vinyl copolymer above. After polymerization, the solvent in the polymerization can be used without being removed from the polymerization solution as a reaction solvent used for reaction in which an isocyanate group-containing unsaturated compound is incorporated into the polymer. The reaction can be carried out in the presence of a catalyst or a polymerization inhibitor. As the catalyst, tin compounds or amines are preferably used. Examples of thereof include dibutyltin laurate, and triethylamine. The amount used of the catalyst is preferably from 0.01 to 20.0% by weight based on the weight of a double bond-containing compound used. Examples of the polymerization inhibitor include hydroquinone, hydroquinone monometyl ether, 2,5-di-t-butylhydroquinone, 2,6-di-t-butylhydroquinone, 2-methylhydroquinone, and 2-t-butylhydroquinone. The amount used of the polymerization inhibitor is ordinarily from 0.01 to 5.0% by weight based on the weight of isocyanate group-containing unsaturated compound used. The reaction process is controlled by measurement of infrared absorption spectra (IR) of the reaction mixture and the reaction is terminated at the time when the isocyanate absorption disappears.

The content of the polymer having in the side chain a carboxyl group and a polymerizable double bond is preferably from 50 to 100% by weight, and more preferably 100% by weight, based on the total weight of the polymeric binder used.

The polymeric binder content of the light sensitive layer is preferably from 10 to 90% by weight, more preferably from 15 to 70% by weight, and still more preferably from 20 to 50% by weight, in view of sensitivity.

### (Ethylenically Unsaturated Compound)

The light sensitive layer (hereinafter also referred to as the photopolymerizable light sensitive layer) in the invention contains an ethylenically unsaturated compound.

Examples of the ethylenically unsaturated compound include conventional radically polymerizable monomers, and polyfunctional monomers and polyfunctional oligomers each having plural ethylenically unsaturated bond ordinarily used in UV-curable resins. The ethylenically unsaturated compound is not specifically limited, but an ethylenically unsaturated compound having in the molecule a photo-oxidation group is preferred.

As the photo-oxidation group, there are a thio group, a thioether group, a ureido group, an amino group (primary, secondary or tertiary), and an enol group. Examples thereof include a triethanolamino group, a triphenylamino group, a thioureido group, an imidazolyl group, an oxazolyl group, a thiazolyl group, an acetylacetonyl group, an N-phenylglycine residue, and an ascorbic acid residue. Among these, a secondary or tertiary amino group is preferred.

In the invention, an ethylenically unsaturated compound having in the molecule an amide bond and a secondary or tertiary amino group is preferred as the ethylenically unsaturated compound.

The ethylenically unsaturated compound having in the molecule an amide bond and a secondary or tertiary amino group forms a layer with high adhesion and high strength. High adhesion and high strength of the layer result from dispersion force or intermolecular force of the amide bond, and from photo-oxidation of the secondary or tertiary amino group, which increases cross-linking density on exposure.

As the photo-oxidation group exhibiting the effects described above, there are a thio group, a thioether group, a ureido group, an amino group (primary, secondary or tertiary), and an enol group. Examples thereof include a triethanolamino group, a triphenylamino group, a thioureido group, an imidazolyl group, an oxazolyl group, a thiazolyl group, an acetylacetonyl group, an N-phenylglycine residue, and an ascorbic acid residue. Among these, a secondary or tertiary amino group is preferred.

Examples of the compound having a photo-oxidation group include compounds described in European patent publication Nos. 287,818, 353,389 and 364,735. Among them, preferred are compounds having a tertiary amino group and a urethane group and compounds having a ureido group and a urethane group.

As compounds having a photo-oxidation group and a urethane group, there are those disclosed in Japanese Patent O.P.I. Publication No. 63-260909, Japanese Patent No. 2669849, and Japanese Patent O.P.I. Publication Nos. 6-35189 and 2001-125255.

The most preferred compound, an ethylenically unsaturated compound containing in the molecule an amide bond and a secondary or tertiary amino group will be explained in detail below.

The ethylenically unsaturated compound containing in the molecule an amide bond and a secondary or tertiary amino group has a solubility in 25° C. pure water of preferably not less than 1% by weight, more preferably not less than 3% by weight, still more preferably not less than 5% by weight, and most preferably not less than 10% by weight.

As the ethylenically unsaturated compound above, there is, for example, a reaction product (hereinafter also referred to as an ethylenicahly unsaturated reaction product) of three components, a polyhydric alcohol (a) having a secondary or tertiary amino group in the molecule, a polyisocyanate (b), and a compound (c) having both a hydroxyl group and an addition polymerizable ethylenically double bond in the molecule.

The polyhydric alcohol (a), polyisocyanate (b) and compound (c) above will be explained in detail below.

### Polyhydric alcohol (a) having a secondary or tertiary amino group in the molecule

### Polyhydric alcohol (a) having a secondary or tertiary amino group in the molecule

Examples of the polyhydric alcohol (a) include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N, N′, N′-tetra-2-hydroxypropylethylenediamine, p-tolyldiethanolamine, N,N, N′, N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

### Polyisocyanate (b)

The polyisocyanate (b) refers to a compound having in the molecule two or more of an isocyanate group, and may be a polyol, biuret or isocyanuric acid adduct of a polyisocyanate.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

There are, further, diisocyanates such as norbornene diisocyanate, m-phenylene diisocyanate, p-phenylene diisocyanate, 2,6-tolylene diisocyanate, 2,6-tolylene diisocyanate, 2,4-tolylene diisocyanate, naphthalene-1,4-diisocyanate, 4,4′-diphenylmethane diisocyanate, polymeric diphenylmethane diisocyanate, dicyclohexylmethane-4,4′-diisocyanate, 5-isocyanate-1-(isocyanatemethyl=1,3,3-trimethylcyclohexane, 3,3′-dimethyldiphenylmethane-4,4′-diisocyanate, xylylene-1,4-diisocyanate, 4,4′-diphenylpropane diisocyanate, trimethylene diisocyanate, hexamethylene diisocyanate, propylene-1,2-diisocyanate, butylene-1,2-diisocyanate, cyclohexylene-1,2-diisocyanate, and cyclohexylene-1,4-diisocyanate.

There are, further, triisocyanates such as 4,4′,4″-triphenylmethane triisocyanate and toluene-2,4,6-triisocyanate, and tetraisocyanates such as-4,4′-dimethyldiphenylmethane-2,2′,5,5′-tetraisocyanate. As the adduct of polyisocyanates and polyols, there are, for example, a trimethylolpropane adduct of hexamethylene diisocyanate, a trimethylolpropane adduct of 2,4-tolylene diisocyanate, a trimethylolpropane adduct of xylylene diisocyanate, and a hexanetriol adduct of tolylene diusocyanate. The polyisocyanate is not limited to the compound as described above, and several kinds thereof may be used in combination.

### Compound (c) having both a hydroxyl group and an addition polymerizable ethylenically double bond in the molecule

Examples of the compound having both a hydroxyl group and an addition polymerizable ethylenically double bond in the molecule is not specifically limited, but include 2-hydroxyethyl methacrylate, 2-hydroxyethyl acrylate, 4-hydroxybutyl acrylate, 2-hydroxypropylene-1,3-dimethacrylate, and 2-hydroxypropylene-1-methacrylate-3-acrylate.

The reaction product can be synthesized according to the same method as a conventional method in which a urethaneacrylate compound is ordinarily synthesized employing a diol, a diisocyanate and an acrylate having a hydroxyl group.

Examples of the reaction product of a polyhydric alcohol having a tertiary amino group in the molecule, a diisocyanate, and a compound having a hydrbxyl group and an addition polymerizable ethylenically double bond in the molecule will be listed below.
M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone-diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2-moles), and 2-hydroxypropylene-1-methacrylate-3-acrylate (2 moles)
M-4: A reaction product of N-n-butyldiethanolamine (1mole), 1,3-di(cyanatomethyl)benzene (2 moles), and 2-hydroxypropylene-1-methacrylate-3-acrylate (2 moles)
M-5: A reaction product of N-methyldiethanolamine (1 mole), tolylene-2,4-diisocyanate (2 moles), and 2-hydroxypropylene-1,3-dimethacrylate (2 moles).

The reaction product as described above has a solubility in 25° C. pure water of preferably not less than 1% by weight, more preferably not less than 3% by weight, still more preferably not less than 5% by weight, and most preferably not less than 10% by weight, which makes it possible to attain the object of the invention.

In the invention, an ethylenically unsaturated compound having a specific property of these is preferably used, and an ethylenically unsaturated compound further containing a polyhydric alcohol unit having no amino group (the fourth component) in addition to the three components above is preferred. The polyhydric alcohol having no amino group will be explained in detail below.

### Polyhydric Alcohol (d) Having No Amino Group

Examples of the polyhydric alcohol (d) having no amino group include polyhydric alcohols such as ethylene glycol, 1,2- or 1,3-propylene glycol, butylene glycol, diethylene glycol, triethylene glycol, tetraethylene glycol, dipropylene glycol, 1,3- or 1,4-butane diol, 1,5-pentane diol, 1,6-hexane diol, neopentyl glycol, 2-methylpertane diol, hydrogenated bisphenol A, polyethylene glycol, polypropylene glycol, polybutylene glycol, polytetramethylene glycol, polycaprolactone, trimethylolethane, trimethylolpropane, polytrimethylol-propane, pentaerythritol, polypentaerythritol, sorbitol, mannitol, glycerin and polyglycerin; polyesterpolyols such as reaction products of the polyhydric alcohols with polybasic acids such as maleic anhydride, maleic acid, fumaric acid, itaconic anhydride, itaconic acid, adipic acid, phthalic acid, phthalic anhydride, terephthalic acid, and isophthalic acid; caprolactone-modified polyols; polyolefin type polyols; polycarbonate type polyols; and polybutadiene type polyols.

Other examples of the polyhydric alcohol (d) include aliphatic polyhydric alcohols such as 1,3-propanediol, 1,7-heptanediol, 1,8-octanediol, 2,3-dihydroxybutane, 1,2-dihydroxybutane, 1,3-dihydroxybutane, 2,2-dimethyl-1,3-propanediol, 2,4-pentanediol, 2,5-pentanediol, 3-metyl-1,5-pentanediol, 1,4-cyclohaxanedimethanol, dihydrbxycyclohexane, 1,2,6-trihydroxycyclohexanei phenylethylene glycol, 1,1,1-trimethylolpropane, hexanetriol, pentaerythritol, and glycerin; condensation products of alkylene oxides with aromatic polyhydric alcohols such as 1,4-di(.2-hydroxyethoxy)benzene and 1,3-bis(2-hydroxyethoxy)benzene, p-xylylene glycol, m-xylylene glycol, α,α′-dihydroxy-p-isopropylbenzene, 4,4′-dihydroxydiphenylmethane, 2-(p,p′-dihydroxydiphenylmethyl)benzyl alcohol, 4,4′-dihydroxydiphenylsulfone, 4,4′-dihydroxydiphenylsulfide, an ethylene oxide adduct of 4,4′-isopropylidenediphenol, and a propylene oxide adduct of 4,4′-isopropylidenediphenol.

Examples of the ethylenically unsaturated compound containing the fourth component will be listed below.
M-6: A reaction product of triethanolamine (1 mole), hexane-1,6-diisocyanate (3 moles), 2-hydroxyethyl methactylate (3 moles) and diethylene glycol (3 moles)
M-7: A reaction product of triethanolamine (1 mole), isophorone diisocyanate (3 moles), 2-hydroxyethyl methacrylate (3 moles) and ethylene glycol (3moles)
M-8: A reaction product of N-n-butyldiethanolamine (1 mole), 1,3-bis(1-cyanato-1-methylethyl)benzene (2 moles), 2-hydroxypropylene-1-methacrylate-3-acrylate (2 moles) and diethylene glycol (2 moles)
M-9: A reaction product of N-n-butyldiethanolamine (1 mole), 1,3-di(cyanatomethyl)benzene (2 moles), 2-hydroxypropylene-1-methacrylate-3-acrylate (2 moles) and diethylene glycol (2 moles)
M-10: A reaction product of N-methyldiethanolamine (1 mole), tolylene-2,4-diisocyanate (2 moles), 2-hydroxypropylene-l,3-dimethacrylate (2 moles) and diethylene glycolC (2 moles)

It is preferred that the content of Compound (c) in the ethylenically unsaturated reaction product is less. The content by mole of compound (c) in the ethylenically unsaturated reaction product is preferably less than 40%, more preferably less than 30%, and still more preferably less than 25%.

Examples of the ethylenically unsaturated reaction product containing compound (c) in less amount will be listed below.
M-11: A reaction product of N-n-butyldiethanolamine (2 moles), 1,3-bis(1-cyanato-1-methylethyl)benzene (3 moles) and 2-hydroxypropylene-1-methacrylate-3-adrylate (2 moles)
M-12: A reaction product of N-n-butyldiethanolamine (3mole), hexamethylene diisocyanate (4 moles) and 2-hydroxypropylene-1-methacrylate-3-acrylate (2 moles)
M-13: A reaction product of N-methyldiethanolamine (2 mole), tolylene-2,4-diisocyanate (3moles) and 2-hydroxypropylene-1,3-dimethacrylate (2 moles)

In the invention, various ethylenically unsaturated compounds other than the compounds described above can be used in combination. Such compounds are not specifically limited, but preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxyhexyl acrylate, or 1,3-dioxolanyl acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional adrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triacrylate, propionic acid dipentaerythritol triacrylate, propionic acid dipentaerythritol tetraacrylate, hydroxypivalylaldehyde modified dimethylolpropane triacrylate or EO-modified products thereof; and a methacrylate, itaconate, crotonate or maleate alternative of the above polyfunctional acrylate.

A prepolymer can be used as the ethylenically unsaturated compound. Examples of the prepolymer include compounds described later and prepolymers with a photopolymerization property obtained by incorporating an acryloyl or methacryloyl group into a prepolymer with an appropriate molecular weight. These prepolymers can be used singly or as an admixture of the above described monomers. and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate.2-hydroxyethylacrylate, hydroxyethylphthalyl methacrylate.xylenediisocyanate, 1,2-polybutadieneglycol.tolylenediisocyanate.2-hydroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane.diisocyanate.2-hydroxyethylacrylate; an alkyd modified acrylate obtained by incorporating a methacroyl group in an oil modified alkyd resin; and a spiran resin acrylate.

Further, examples of the ethylenically unsaturated compounds include a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate or a urethane modified acrylate; and an addition polymerizable oligomer or prepolymer having a structural unit derived from the above monomer.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV.EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

The ethylenically unsaturated compound content of the light sensitive layer is preferably from 1.0 to 80.0% by weight, and more preferably from 3.0 to 70.0% by weight.

In the invention, the content ratio by weight of the polymerizable ethylenically unsaturated compound to the polymeric binder is preferably from 0.5 to 2.2.

### (Photopolymerization Initiator)

The light sensitive layer in the invention contains a photopolymerization initiator.

The photopolymerization initiator in the invention is a compound which initiates polymerization of an ethylenically unsaturated compound on light exposure. As the photopolymerization initiator is used a biimidazole compound, an iron arene complex, a titanocene compound, a polyhalogenated compound or a monoalkyltriaryl borate compound. These photopolymerization initiators can be used as an admixture, of two or more kinds thereof. Among these, a polyhalogenated compound, a biimidazole compound or an iron arene complex is preferred. A combination of a polyhalogenated compound and an iron arene complex is especially preferred.

### (Biimidazole Compound)

The biimidazole compound is a derivative of bilmidazole, and examples thereof include those disclosed in for example, Japanese Patent O.P.I. Publication No. 2003-295426. In the invention, a hexaarylbisimidazole (HABI, a dimer of a triarylimidazole) compound is preferred as the biimidazole compound. The synthetic method of the hexaarylbisimidazoles (HABI, dimmers of triarylimidazoles) is disclosed in DIELECTRIC 1470154, and use thereof in a photopolymerizable composition is disclosed in EP 24629, EP 107792, U.S. Pat. No. 4,410,621, EP 215453 and DE 321312.

Preferred examples of the biimidazole compound include 2,4,5,2′,4′,5′-hexaphenylbisimidazole, 2,2′-bis(2-chlorophenyl)-4,5,4′,5′-tetraphenylbisimidazole, 2,2′-bis(2-bromophenyl)-4,5,4′,5′-tetraphenylbisimidazole, 2,2′-bis(2,4-dichlorophenyl)-4,5,4′,5′-tetraphenylbisimidazole, 2,2′-bis(2-chlorophenyl)-4,5,4′,5′-tetrakis(3-methoxyphenyl)bisimidazole, 2,2′-bis(2-chlorophenyl)-4,5,4′,5′-tetrakis(3,4,5-trimethoxyphenyl)bisimidazole, 2,5,2′,5′-tetrakis(2-chlorophenyl)-4,4′-bis(3,4-dimethoxyphenyl)bisimidazole, 2,2′-bis(2,6-dichlorophenyl)-4,5,4′,5′-tetraphenylbisimidazole, 2,2′-bis(2-nitrophenyl)-4,5,4′,5′-tetraphenylbisimidazole, 2,2′-di-o-tolyl-4,5,4′,5′-tetraphenylbisimidazole, 2,2′-bis(2-ethoxyphenyl)-4,5,4′,5′-tetraphenylbisimidazole, and 2,2′-bis(2,6-difluorophenyl)-4,5,4′,5′-tetraphenylbisimidazole.

### (Iron Arene Complex)

The iron arene complex used in the invention is a compound represented by formula (1) below.

(A-Fe-B)+⁺X⁻ Formula (1)

wherein A represents a substituted or unsubstituted cyclopentadienyl group or a substituted or unsubstituted cyclohexadienyl group; B represents a compound having an aromatic ring; and X⁻is an anion.

Examples of the compound having an aromatic ring include benzene, toluene, xylene, cumene, naphthalene, 1-methylnaphtalene, 2-methylnaphtalene, biphenyl, fluorene, anthracene and pyrene. Examples of X⁻include PF₆⁻, BF₄⁻, SbF₆⁻, AlF₄⁻, and CF₃SO₃⁻. The substituents of the substituted or unsubstituted cyclopentadienyl group or a substituted or unsubstituted cyclohexadienyl group include an alkyl group such as methyl, ethyl, etc., a cyano group, an acetyl group and a halogen atom.

Examples of the iron arene complex include:
Fe-1: (η6-benzene)(η5-cyclopentadienyl)iron (2) hexafluorophosphate;
Fe-2: (η6-toluene) (η5-cyclopentadienyl)iron (2) hexafluorophosphate;
Fe-3: (η6-cumene)(η5-cyclopentadienyl)iron (2) hexafluorophosphate;
Fe-4: (η6-benzene)(η5-cyclopentadienyl)iron (2) hexafluoroarsenate;
Fe-6: (η6-benzene)(η5-cyclopentadienyl)iron (2) tetrafluoroborate;
Fe-6: (η6-naphthalene)(η5-cyclopentadienyl)iron (2) hexafluorophosphate;
Fe-7: (η6-anthracene)(η5-cyclopentadienyl)iron (2) hexafluorophosphate;
Fe-8: (η6-pyrene)(η5-cyclopentadienyl)iron (2) hexafluorophosphate;
Fe-9: (η6-benzene)(η5-cyanocyclopentadienyl)iron (2) hexafluorophosphate;
Fe-10: (η6-toluene) (η5-acetylcyclopentadienyl)iron (2) hexafluorophosphate;
Fe-11: (η6-cumene)(η5-cyclopentadienyl)iron (2) tetrafluoroborate;
Fe-12: (η6-benzene) (η5-carboethoxycyclohexadienyl)iron (2) hexafluorophosphate;
Fe-13: (η6-benzene) (η5-1,3-dichlorocyclohexadienyl)iron (2) hexafluorophosphate;
Fe-14: (η6-cyanobenzene)(η5-cyclohexadienyl)iron (2) hexafluorophosphate;
Fe-15: (η6-acetophenone)(η5-cyclohexadienyl)iron (2) hexafluorophosphate;
Fe-16: (η6-methyl benzoate)(η5-cyclopentadienyl)iron (2) hexafluorophosphate;
Fe-17: (η6-benzene sulfonamide)(η5-cyclopentadienyl)iron (2) tetrafluoroborate;
Fe-18: (η6-benzamide)(η5-cyclopentadienyl)iron (2) hexafluorophosphate;
Fe-19: (η6-cyanobenzene)(η5-cyanocycldpentadienyl)iron (2) hexafluorophosphate;
Fe-20: (η6-chloronaphthalene)(η5-cyclopentadienyl)iron (2) hexafluorophosphate;
Fe-21: (η6-anthracene)(η5-cyanocyclopentadienyl)iron (2) hexafluorophosphate;
Fe-22: (η6-chlorobenzene)(η5-cyclopentadienyl)iron (2) hexafluorophosphate; and
Fe-23: (η6-chlorobenzene)(η5-cyclopentadienyl)iron (2) tetrafluoroborate.

These compounds can be synthesized according to a method described in Dokl. Akd. Nauk. SSSR 149 615 (1963).

### (Titanocene Compound)

The titanocene-compounds are described in Japanese Patent O.P.I. Publication Nos. 63-41483 and 2-291. Preferred examples of the titanocene compounds include bis(cyclopentadienyl)-Ti-di-chloride, bis(cyclopentadienyl)-Ti-bis-phenyl, bis(cyclopentadienyl)-Ti-bis-2,3,4,5,6-pentaflurophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 784, produced by Ciba Speciality Chemicals Co.), bis(cyclopentadienyl)-bis(2,4,6-trifluoro-3-(pyry-1-yl)phenyl)titanium, and bis(cyclopentadienyl)-bis(2,4,6-trifluoro-3-(2-5-dimethylpyry-1-yl)phenyl)titanium.

### (Polyhalogenated Compound)

The polyhalogenated compound is a compound having a trihalomethyl group, a dihalomethyl group or a dihalomethylene group. In the invention, an oxadiazole compound having in the molecule the group described above as the substituent or a polyhalogenated compound represented by the following formula (2) is preferably used.

R¹−C(Y)₂−(C=O)−R² Formula (2)

wherein R¹ represents a hydrogen atom, a halogen atom, an alkyl group, an aryl group, an acyl group, an alkylsulfonyl group, an arylsulfonyl group, an iminosulfo group or a cyano group; R² represents a monovalent substituent, provided that R¹ and R² may combine with each other to form a ring; and Y represents a halogen atom.

The monovalent substituent represented by R² represents a substituted or unsubstituted alkyl group, a substituted or unsubstituted aryl group, a substituted or unsubstituted heterocyclic ring group, a substituted or unsubstituted alkoxy group, a substituted or unsubstituted aryloxy group, a substituted or unsubstituted amino group or a hydroxyl group.

A polyhalogenated compound represented by the following formula (3) is especially preferably used.

C(Y)₃−(C=O)−X−R³ Formula (3)

wherein R³ represents a monovalent substituent; X represents —O- or —NR⁴- in which R⁴ represents a hydrogen atom or an alkyl group, provided that when X represents —NR⁴-, R³ and R⁴ may combine with each other to form a ring; and Y represents a halogen atom.

The monovalent substituent represented by R, represents a substituted or unsubstituted alkyl group, a substituted or unsubstituted aryl group, or a substituted or unsubstituted heterocyclic ring group.

Among these, a polyhalogenated compound having a polyhaloacetylamido group is preferably used.

An oxadiazole compound having a polyhalomethyl group as the substituent also is preferably used.

As the monoalkyltriaryl borate compound, there are those described in Japanese Patent O.P.I. Publication Nos. 62-150242 and 62-143044. Preferred examples of the monoalkyl-triaryl borate compounds include tetra-n-butyl ammonium n-butyltrinaphthalene-1-yl-borate, tetra-n-butylammonium n-butyltriphenylborate, tetra-n-butylammonium triphenyl-mono-t-butylborate, tetra-n-butylammonium n-butyl-tri-(4-tert-butylphenyl)borate, tetra-n-butylammonium n-hexyl-tri-(3-chloro-4-methylphenyl)borate, and tetra-n-butylammonium n-hexyl-tri-(3-fluorophenyl)borate.

In the invention, known photopolymerization initiators other than those described above can be used in combination.

The content of the photopolymerization initiator in the light-sensitive layer is preferably from 0.1 to 20% by weight, and more preferably from 0.1 to 10% by weight, based on the amount of the polymerizable ethylenically unsaturated compound contained in the light sensitive layer.

It is preferred that the light sensitive layer further contains an organic amine (a primary, secondary or tertiary amine). Inclusion of the amine in the light sensitive layer is effective in improving sensitivity, printing durability, and anti-stain property after storage or pre-heating treatment. However, a solution of containing a polymeric binder having an acid value exceeding 120 and the amine has problem in that causes coagulation to produce precipitates in the solution, and is difficult to obtain such effects as described above. A specific combination of the polymer in the invention and such an organic amine greatly enhances the above effects without causing coagulation.

As such an amine, a compound represented by formula (I) below and its multimers are preferred.

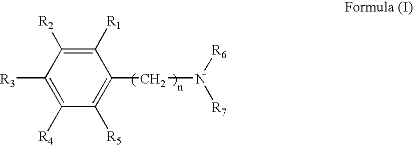

wherein n represents an integer of from 1 to 10; R₁ through R₅ independently represent a hydrogen atom, a halogen atom, a hydroxyl group, a formyl group, a carboxyl group, a cyano group, a nitro group, a sulfo group, a substituted or unsubstituted alkyl group, a substituted or unsubstituted alkenyl group, a substituted or unsubstituted aryl group, a substituted or unsubstituted aromatic heterocyclic group, a substituted or unsubstituted alkoxy group, a substituted or unsubstituted aryloxy group, a substituted or unsubstituted acyl group, a substituted or unsubstituted alkoxycarbonyl group, a substituted or unsubstituted acryloyloxy group, a substituted or unsubstituted alkylcarbonyloxy group, a substituted or unsubstituted alkylthio group, a substituted or unsubstituted sulfonyl group, a substituted or unsubstituted arylthio group, a substituted or unsubstituted amino group or a substituted or unsubstituted amido group; and R₆ and R₇ independently represent a hydrogen atom, a substituted or unsubstituted alkyl group, a substituted or unsubstituted alkenyl group, a substituted or unsubstituted aryl group, a substituted or unsubstituted aromatic heterocyclic group, or a substituted or unsubstituted aryloxy group.

In formula (I), n represents an integer of from 1 to 10, preferably from 1 to 5, and more preferably from 1 to 3.

R₁ through R₅ independently represent a hydrogen atom, a halogen atom, a hydroxyl group, a formyl group, a carboxyl group, a cyano group, a nitro group, a sulfo group, a substituted or unsubstituted alkyl group, a substituted or unsubstituted alkenyl group, a substituted or unsubstituted aryl group, a substituted or unsubstituted aromatic heterocyclic group, a substituted or unsubstituted alkoxy group, a substituted or unsubstituted aryloxy group, a substituted or unsubstituted acyl group, a substituted or unsubstituted alkoxycarbonyl group, a substituted or unsubstituted acryloyloxy group, a substituted or unsubstituted alkylcarbonyloxy group, a substituted or unsubstituted alkylthio group, a substituted or unsubstituted sulfonyl group, a substituted or unsubstituted arylthio group, a substituted or unsubstituted amino group or a substituted or unsubstituted amido group.

It is preferred that R₁ through R₅ independently represent a hydrogen atom, a hydroxyl group, a substituted or unsubstituted alkyl group having a carbon atom number of from 1 to 10 and preferably from 1 to 5, or a substituted or unsubstituted alkoxy group having a carbon atom number of from 1 to 10 and preferably from 1 to 5, provided that at least one of R₁ through R₅ is a hydroxy group.

R₆ and R₇ independently represent a hydrogen atom, a substituted or unsubstituted alkyl group, a substituted or unsubstituted alkenyl group, a substituted or unsubstituted aryl group, a substituted or unsubstituted aromatic heterocyclic group, or a substituted or unsubstituted aryloxy group.

It is preferred that R₆ and R7 independently represent a hydrogen atom, a substituted or unsubstituted alkyl group having a carbon atom number of from 1 to 10, a substituted or unsubstituted alkenyl group having a carbon atom number of from 2 to 10, a substituted or unsubstituted aryl group having a carbon atom number of from 6 to 10, or a substituted or unsubstituted acryloyl. It is more preferred that R₆ and R₇ independently represent a hydrogen atom or a substituted or unsubstituted alkyl group having a carbon atom number of from 1 to 10, and preferably from 1 to 5.

Examples of the substituent of the substituted groups above include an alkyl group, an alkenyl group, an aryl group, an aromatic heterocyclic group, an alkoxy group, an aryloxy group, an acyl group, an alkoxycarbonyl group, an alkenyloxycarbonyl group, an alkylcarbonyloxy group, an acryloyloxy group, a halogen atom, an amino group, an amido group, an acryloyl group, an acryloyloxy group, or a hydroxyl group. These substituents may further have a substituent. Among these substituents described above, an alkyl group, an aryl group, an amino group, an amido group, an alkoxycarbonyl group or a hydroxyl group is preferred.

A preferred compound of formula (I) is a phenol derivative in which at least one of R₁ through R₅ is a hydroxyl group.

The multimers of the compound represented by formula (I) above is a compound in which two or more of the compound represented by formula (I) are combined directly or through a linkage group at the position of at least one of R₁ through R₇ thereof. The linkage group is not limited, as long as it is a polyvalent. The multimers are preferably a dimer, a trimer, a tetramer, or a pentamer.

Typical examples of the compound represented by formula (I) below and its multimers will be listed below, but the invention is not limited thereto.

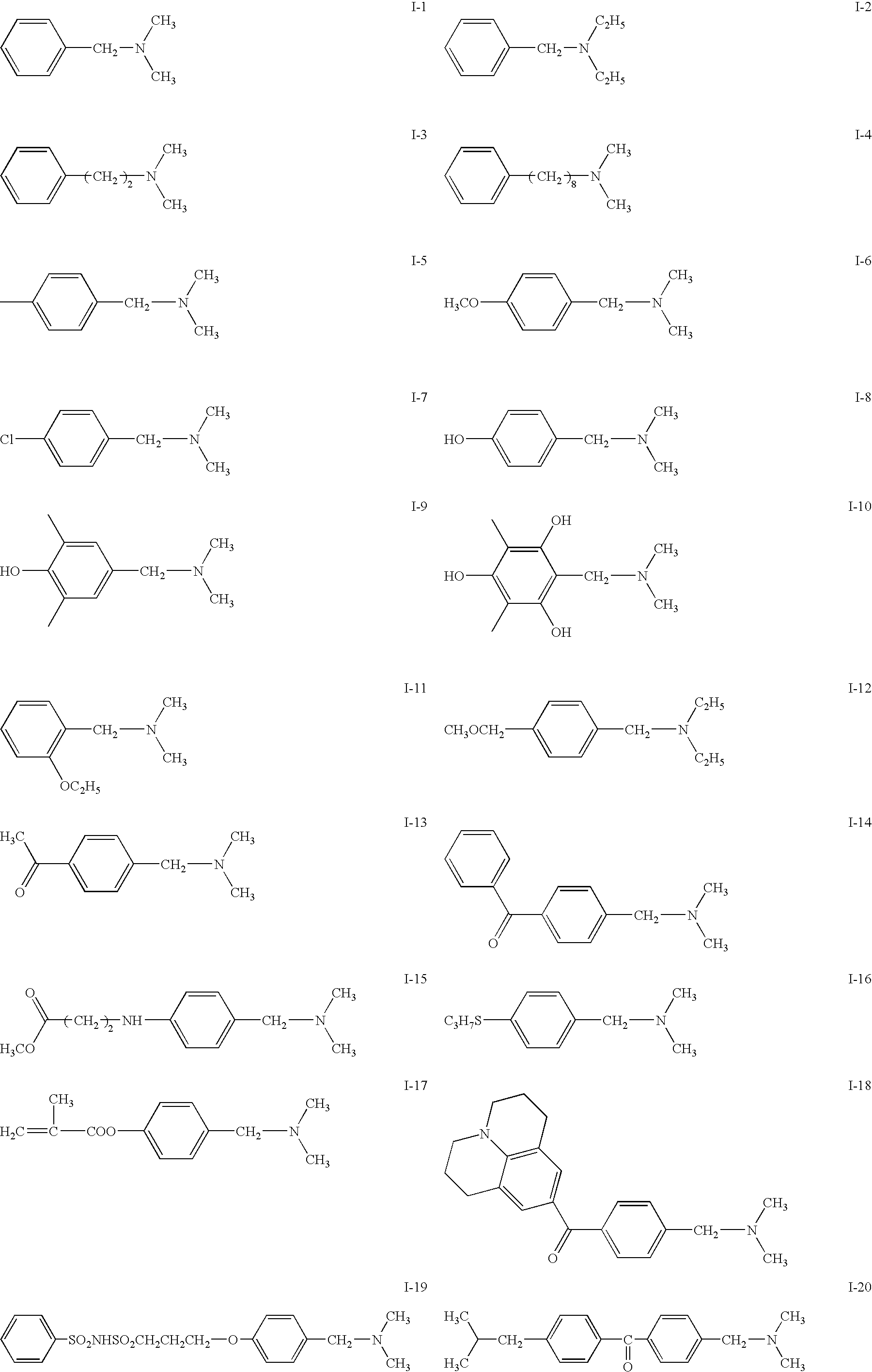

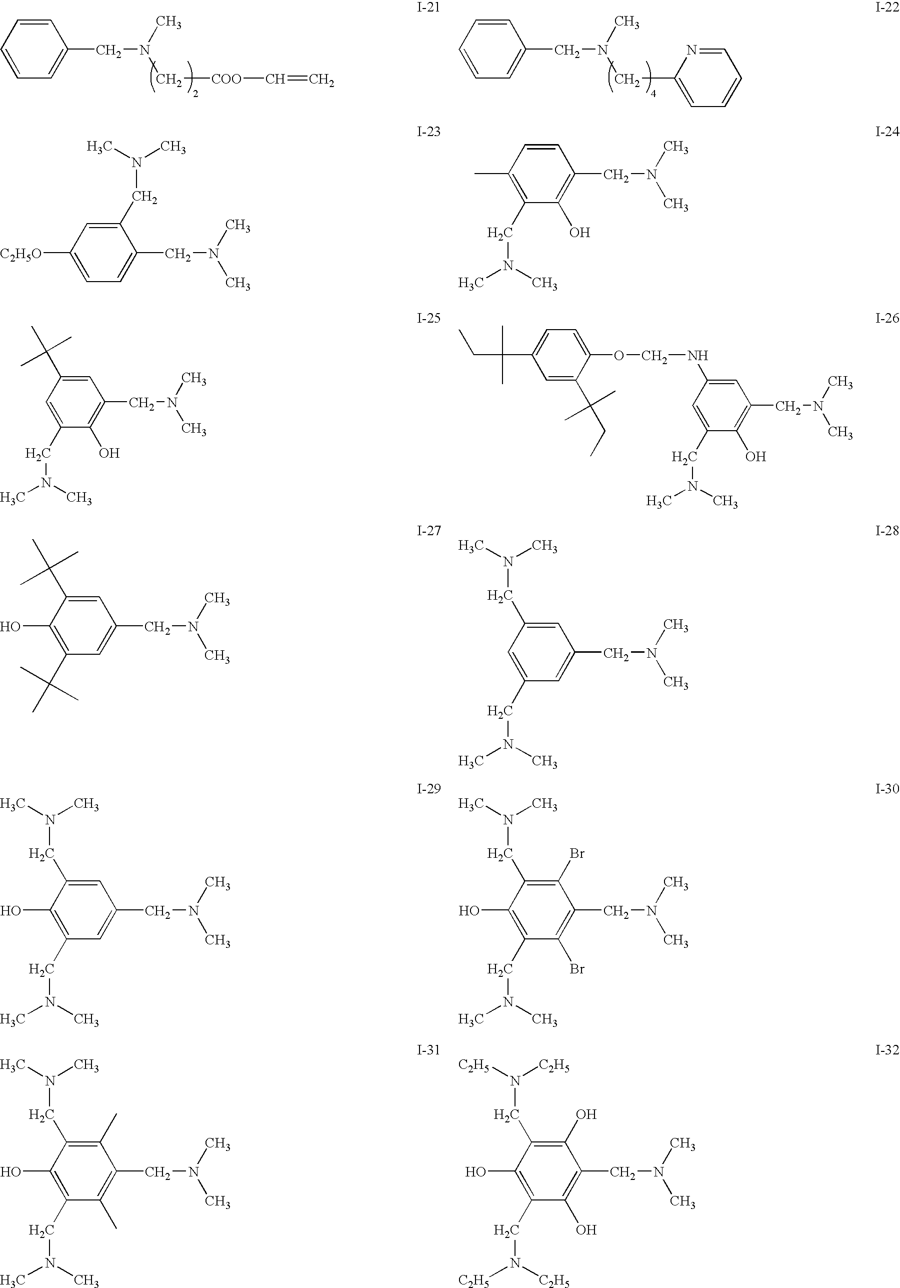

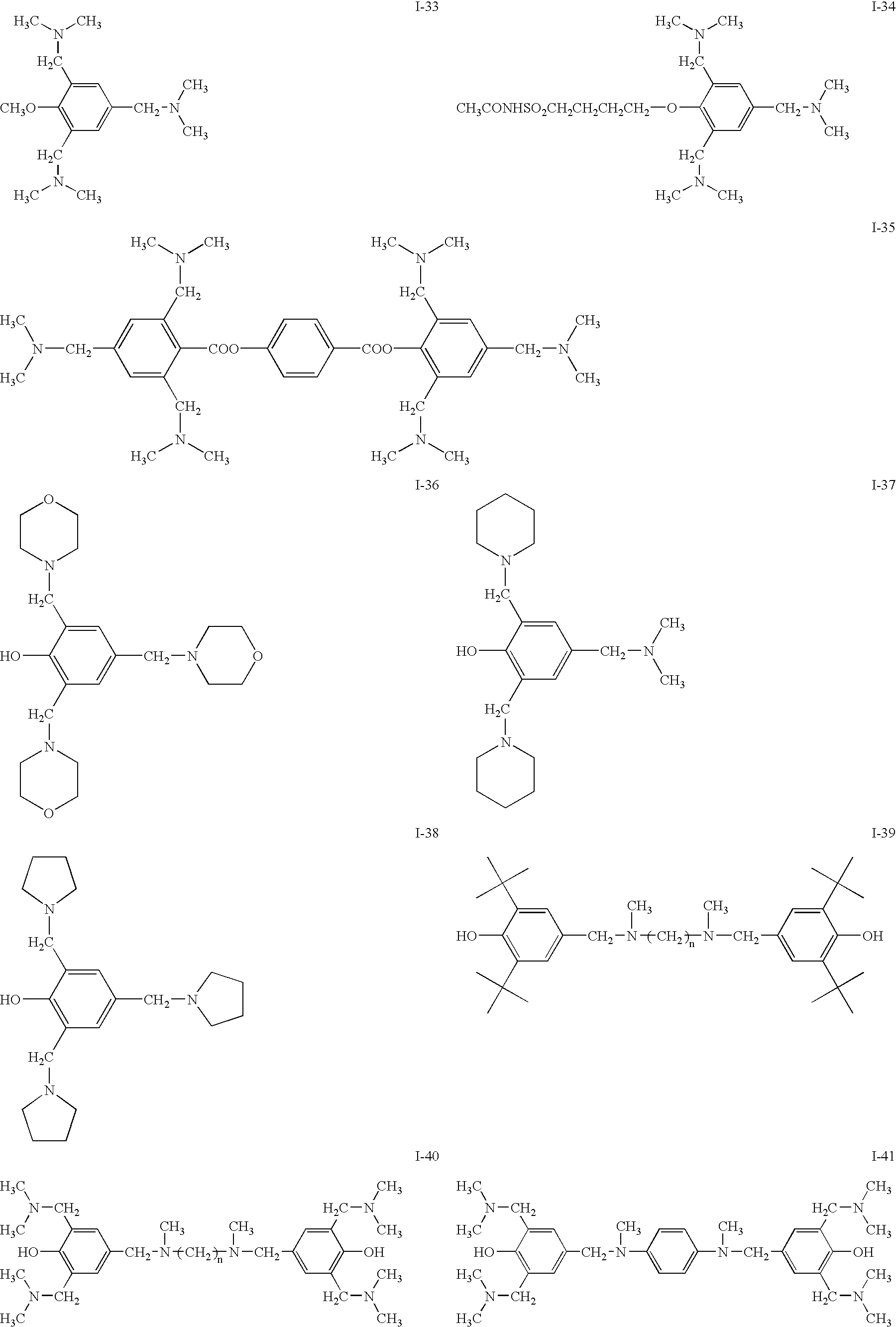

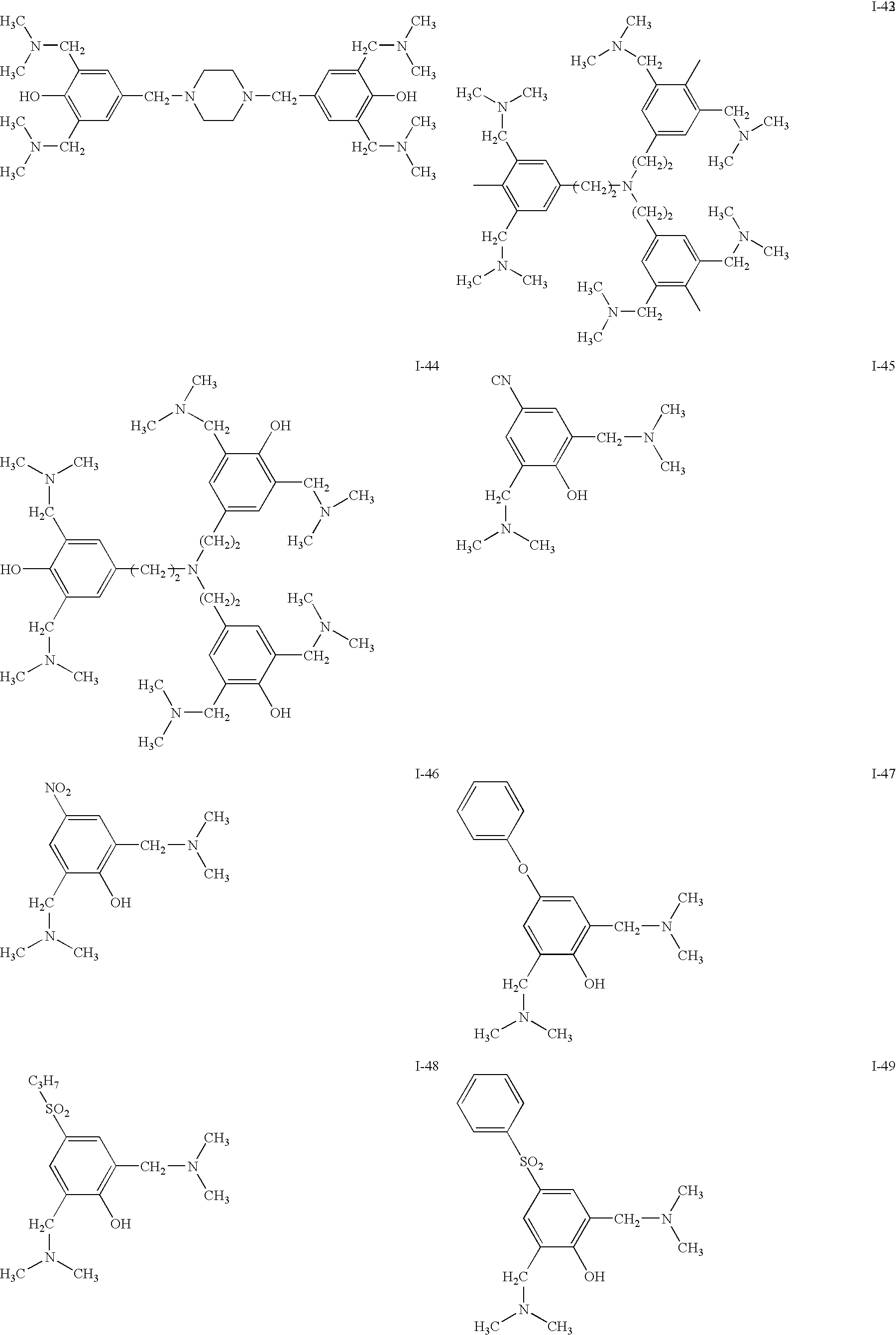

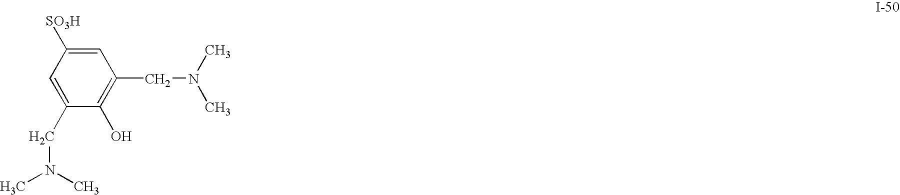

The organic amine in the invention may be any another compound, as long as it has in the molecule a primary, secondary or tertiary amino group. Among these, an organic, amine represented by the following formula (II), is especially preferred.

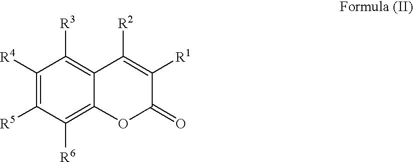

wherein R¹, R², R³, R⁴, R⁵ and R⁶ independently represent a hydrogen atom, an alkyl group, a cycloalkyl group, an alkenyl group, an alkynyl group, an aryl group, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amido group, a carbamoyl group, a ureido group, a sufinyl group, an alkylsulfonyl group, an arylsulfonyl group, an amino group, a halogen atom, a cyano group, a nitro group, or a hydroxyl group, provided that at least one of R¹, R², R³, R⁴, R⁵ and R⁶ is an amino group, and the two nearest group of R¹, R², R³, R⁴, R⁵ and R⁶ may combine with each other to form a ring. The foregoing R¹ to R⁶ substituents may further have the same as those denoted above in R¹ through R⁶.

The content of the organic amine in the light sensitive layer is preferably from 0.1 to 20% by weight, more preferably from 1 to 20% by weight, still more preferably from 3 to 18% by weight, and most preferably from 5 to 15% by weight.

### (Sensitizing Dye)

The light sensitive layer in the invention preferably contains a sensitizing dye. A dye having absorption maximum in the wavelength regions approximate to the emission wavelength of light of the light source is preferred.

In the invention, laser can be used as a light source for recording. Examples of the laser will be described later. When recording is carried out employing a semiconductor laser called a violet laser emitting light with an emission wavelength of from 350 to 430 nm, a dye having absorption maximum in the range of from 350 to 430 nm is preferably used. The dye having absorption maximum in the range of from 350 to 430 nm has is not specifically limited to the chemical structure, as long as it has the characteristics as described above. Examples thereof include sensitizing dyes disclosed in Japanese Patent O.P.I. Publication Nos. 2002-296764, 2002-268239,-2002-268238, 2002-268204, 2002-221790, 2002-202598, 2001-42524, 2000-309724, 2000-258910, 2000-206690, 2000-247763, and 2000-98605, but are not limited thereto.

The following sensitizing dyes can be used as necessary. Examples of dyes capable of sensitizing to visible to near infrared wavelength regions include cyanine, phthalocyanine, merocyanine, porphyrin, a spiro compound, ferrocene, fluorene, fulgide, imidazole, perylene, phenazine, phenothiazine, polyene, an azo compound, diphenylmethane, triphenylmethane, polymethine acridine, cumarin, cumarin derivatives, ketocumarin, quinacridone, indigo, styryl, pyrylium compounds, pyrromethene compounds, pyrazolotriazole compounds, benzothiazole compounds, barbituric acid derivatives, thiobarbituric acid derivatives, ketoalcohol borate complexes, xanthene dyes, and compounds disclosed in EP 568,993, U.S. Pat. No. 4,508,811, and Japanese Patent O.P.I. Publication Nos. 2001-125255 and 11-271969, and 63-260909.

When recording is carried out employing a laser emitting light with an emission wavelength of from 470 to 550 nm, a sensitizing dye having absorption maximum in the range of from 470 to 550 nm is preferably used. The sensitizing dyes having absorption maximum in the range of from 470 to 550 nm has are not specifically limited to the chemical structure, as long as they have the absorption characteristics as described above. Examples thereof include dyes disclosed in Japanese Patent O.P.I. Publication Nos. 2001-125225, 11-271969 and 63-260909, but are not limited thereto.

The sensitizing dye content of the light sensitive layer is preferably from 0.1 to 20% by weight, and more preferably from 0.1 to 10% by weight.

### (Chain Transfer Agent)

The chain transfer agent is a compound added to a polymerization reaction mixture in order to control polymerization degree of polymer, which has function changing kinds of chain transfer substances in the chain polymerization process.

As the chain transfer agent in the invention, radical chain transfer agents as disclosed in EP 107792 are preferred in promoting or controlling polymerization of the polymerizable compound in the invention. As the preferred chain transfer agent, there is a mercapto compound. It is especially preferred that an aromatic heterocyclic mercapto compound represented by formula (RCT) below or a mercapto derivative compound is contained in the light sensitive layer in the invention.

Ar-SM Formula (RCT)

Wherein M represents a hydrogen atom or an alkali metal atom; and Ar represents an aromatic heterocyclic ring or an aromatic heterocyclic condensed ring each containing in the ring at least one atom selected from the group consisting of a nitrogen atom, a sulfur atom, an oxygen atom, a selenium atom and a tellurium atom. Preferred examples of the aromatic heterocyclic ring or aromatic heterocyclic condensed ring include a benzimidazole ring, a naphthimidazole ring, a benzothiazole ring, a naphthothiazole ring, a benzoxazole ring, a naphthoxazole ring, a benzoselenazole ring, a benzotellurazole ring, an imidazole ring, an oxazole ring, a pyrazole ring, a triazole ring, a triazine ring, a pyrimidine ring, a pyridazine ring, a pyrazine ring, a pyridine ring, a purine ring, a quinoline ring, and a quinazoline ring. An aromatic heterocyclic mercapto compound having a chemical structure other than the aforementioned may be used as the chain transfer agent in the invention.

Various additives which can be contained in the light sensitive layer, a support, a protective layer, a coating method of a light sensitive layer coating liquid on the support and a manufacturing method of a light sensitive planographic printing plate material will be explained below.

### (Various Additives)

The light sensitive layer in the invention is preferably added with a polymerization inhibitor, in order to prevent undesired polymerization of the ethylenically unsaturated monomer during the manufacture or after storage of light sensitive planographic printing plate material. Examples of the polymerization inhibitor include hydroquinone, p-methoxyphenol, di-t-butyl-p-cresol, pyrrogallol, t-butylcatechol, benzoquinone, 4,4′-thiobis (3-methyl-6-t-butylphenol), 2,2′-methylenebis (4-methyl-6-t-butylphenol), N-nitrosophenylhydroxylamine cerous salt, and 2-t-butyl-6-(3-t-butyl-6-hydroxy-5-mrthylbenzyl)-4-methylphenyl acrylate.

The polymerization inhibitor content is preferably 0.01 to 5% by weight based on the total solid content of the light sensitive layer. Further, in order to prevent undesired polymerization induced by oxygen, behenic acid or a higher fatty acid derivative such as behenic amide may be added to the layer. After the light sensitive layer is coated layer, the coated layer may be dried so that the higher fatty acid derivative is localized at the vicinity of the surface of the light sensitive layer. The content of the higher fatty acid derivative is preferably 0.5 to 10% by weight, based on the total solid content of the light sensitive layer.

A colorant can be also used. As the colorant can be used known materials including commercially available materials. Examples of the colorant include those described in revised edition “Ganryo Binran”, edited by Nippon Ganryo Gijutu Kyoukai (publishe by Seibunndou Sinkosha), or “Color Index Binran”. Pigment is preferred.

Kinds of the pigment include black pigment, yellow pigment, red pigment, brown pigment, violet pigment, blue pigment, green pigment, fluorescent pigment, and metal powder pigment. Examples of the pigment include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment, anthanthrone pigment, triphenedioxazine pigment, vat dye pigment, phthalocyanine pigment or its derivative, or quinacridone pigment).

Among these pigment, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used. The pigment content is preferably 0.1 to 10% by weight, and more preferably 0.2 to 5% by weight, based on the total solid content of the photopolymerizable light sensitive layer composition.

A purple pigment or a blue pigment is preferably utilized in view of absorption of light with the aforesaid photosensitive wavelength region and image visibility after development. Such pigments include, for example, Cobalt Blue, cerulean blue, Alkali Blue, Phonatone Blue 6G, Victoria Blue Lake, metal-free Phthalocyanine Blue, Phthalocyanine Fast Sky Blue, Indathrene Blue, indigo, Dioxane Violet, Isoviolanthrone Violet, Indanthrone Blue and Indanthrone BC. Among them, more preferable are Phthalocyanine Blue and Dioxane Violet.

The light sensitive layer can contain surfactants as a coating improving agent as long as the performance of the invention is not jeopardized. Among these surfactants, a fluorine-contained surfactant is preferred.

Further, in order to improve physical properties of the cured light sensitive layer, the layer can contain an inorganic filler or a plasticizer such as dioctyl phthalate, dimethyl phthalate or tricresyl phosphate.

The light sensitive planographic printing plate material of the invention is manufactured by preparing a light sensitive layer coating liquid containing the above-described components and then coating the light sensitive layer coating liquid on an aluminum support (described later) according to a conventional coating method and dried to form a light sensitive layer on the support. Examples of the coating method include an air doctor coating method, a blade coating method, a wire bar coating method, a knife coating method, a dip coating method, a reverse roll coating method, a gravure coating method, a cast coating methods a curtain coating method, and an extrusion coating method. The drying temperature of the coated light sensitive layer is preferably from 60 to 160° C., more preferably from 80 to 140° C., and still more preferably from 90 to 120° C.

The solvents used in the preparation of the light sensitive layer coating liquid include an alcohol such as sec-butanol, isobutanol, n-hexanol, or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactate, diethyl oxalate, or methyl benzoate.

In the invention, the thickness of the light sensitive layer is preferably from 0.5 to 4.0 g/m², and more preferably from 1.0 to 3.0 g/m².

### (Protective Layer, Oxygen Shielding Layer)

In the invention, a protective layer is preferably provided on the photopolymerizable light sensitive layer. It is preferred that the protective layer (oxygen shielding layer) is highly soluble in the developer as described later (generally an alkaline solution). The protective layer preferably contains polyvinyl alcohol and polyvinyl pyrrolidone. Polyvinyl alcohol has the effect of preventing oxygen from transmitting and polyvinyl pyrrolidone has the effect of increasing adhesion between the oxygen shielding layer and the photopolymerizable light sensitive layer adjacent thereto.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

In the planographic printing plate material in the invention, adhesive strength between the protective layer and the image formation layer is preferably not less than 35 mN/mm, more preferably not less than 50 mN/mm, and still more preferably not less than 75 mN/mm. Preferred composition of the protective layer is disclosed in Japanese Patent O.P.I. Publication No. 10-10742. The adhesive strength in the invention can be measured according to the following procedure.

When an adhesive tape with sufficient adhesive strength having a predetermined width is adhered onto the protective layer, and then peeled at an angle of 90° to the plane of the planographic printing plate material, strength necessary to peel the protective layer from the image formation layer is measured as the adhesive strength.

The protective layer may further contain a surfactant or a matting agent. The protective layer is formed, coating on the photopolymerizable light sensitive layer a coating solution in which the above protective layer composition is dissolved in an appropriate coating solvent, and drying. The main solvent of the coating solution is preferably water or an alcohol solvent such as methanol, ethanol, or iso-propanol.

The thickness of the protective layer is preferably 0.1 to 5.0 μm, and more preferably 0.5to 3.0 μm.

### (Support)

As the support in the invention, an aluminum support having a hydrophilic surface is preferably used, and may be a support made of pure aluminum or an aluminum alloy. As the aluminum alloy, there can be used various ones including an alloy of aluminum and a metal such as silicon, copper, manganese, magnesium, chromium, zinc, lead, bismuth, nickel, titanium, sodium or iron.

It is preferable that an aluminum plate for the support in the invention is subjected to degreasing treatment for removing rolling oil prior to surface roughening (graining). The degreasing treatments include degreasing treatment employing solvents such as trichlene and thinner, and emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting plate is preferably subjected to desmut treatment in an aqueous solution of an acid such as phosphoric acid, nitric acid, sulfuric acid, chromic acid, or a mixture thereof, since smut is produced on the surface of the plate. Subsequently, surface roughening is carried out. In the invention, electrolytic surface roughening is carried out, but prior to the electrolytic surface roughening, mechanical surface roughening is preferably carried out.

Though there is no restriction for the mechanical surface roughening method, a brushing roughening method and a honing roughening method are preferable. The brushing roughening method is carried out by rubbing the surface of the support with a rotating brush with a brush hair with a diameter of 0.2 to 0.8 mm, while supplying slurry in which volcanic ash particles with a particle size of 10 to 100 μm are dispersed in water to the surface of the support. The honing roughening method is carried out by ejecting obliquely slurry with pressure applied from nozzles to the surface of the support, the slurry containing volcanic ash particles with a particle size of 10 to 100 μm dispersed in water. A surface roughening can be also carried out by laminating the plate surface with a sheet on the surface of which abrading particles with a particle size of from 10 to 100 μm was coated at intervals of 100 to 200 μm and at a density of 2.5×10³ to 10×10³/cm², and applying pressure to the sheet to transfer the roughened pattern of the sheet and roughen the surface of the plate.

After the plate has been mechanically roughened as above, it is preferably dipped in an acid or an aqueous alkali solution in order to remove abrasives and aluminum dust, etc. which have been embedded in the surface of the plate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, an aqueous alkali solution of for example, sodium hydroxide is preferably used. The dissolution amount of aluminum is preferably 0.5 to 5 g/m². After the support has been dipped in the aqueous alkali solution, it is preferable for the plate to be dipped in an acid such as phosphoric acid, nitric acid, sulfuric acid and chromic acid, or in a mixed acid thereof, for neutralization.

The electrolytic surface roughening is carried out in an acidic electrolytic solution. As the acidic electrolytic solution, a 0.4 to 2.8% by weight hydrochloric acid or nitric acid solution is used. The concentration of hydrochloric acid or nitric acid in the electrolytic solution is preferably from 1 to 2.3% by weight. The electrolytic surface roughening is carried at a current density (in terms of effective value) of from 30 to 100 A/dm² for 10 to 120 seconds. The current density is preferably from 30 to 80 A/dm², and more preferably from 40 to 75 A/dm².

Electrolytic surface roughening temperature, although not specifically limited, is preferably from 5 to 80° C., and more preferably from 10 to 60° C. Although not specifically limited also, voltage applied is preferably from 1 to 50 V, more preferably from 10 to 30 V, and still more preferably from 1 to 50 V. Although not specifically limited also, quantity of electricity applied is preferably from 100 to 5000 C/dm², and more preferably from 100 to 2000 C/dm².

It is possible to optionally add, to the electrolytic solution, nitrates, chlorides, amines, aldehydes, phosphoric acid, chromic acid, boric acid, acetic acid or oxalic acid.

After the plate has been electrolytically surface roughened as above, it is preferably dipped in an acid or an aqueous alkali solution in order to remove aluminum dust, etc. produced in the surface of the plate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum is preferably 0.5 to 5 g/m². After the plate has been dipped in the aqueous alkali solution, it is preferable for the plate to be dipped in an acid such as phosphoric acid, nitric acid, sulfuric acid and chromic acid, or in a mixed acid thereof, for neutralization.

After the surface roughening, anodizing treatment may be carried out. There is no restriction in particular for the method of anodizing treatment used in the invention, and known methods can be used. The anodizing treatment forms an anodization film on the surface of the aluminum plate. For the anodizing treatment there is preferably used a method of applying a current density of from 1 to 10 A/dm² to an aqueous solution containing sulfuric acid and/or phosphoric acid in a concentration of from 10 to 50%, as an electrolytic solution. However, it is also possible to use a method of applying a high current density to sulfuric acid as described in U.S. Pat. No. 1,412,768, a method to electrolytically etching the support in phosphoric acid as described in U.S. Pat. No. 3,511,661, or a method of employing a solution containing two or more kinds of chromic acid, oxalic acid, malonic acid, etc. The coated amount of the formed anodization film is suitably 1 to 50 mg/dm², and preferably 10 to 40 mg/dm². The coated amount of the formed anodization film can be obtained from the weight difference between the aluminum plates before and after dissolution of the anodization film. The anodization film of the aluminum plate is dissolved employing for example, an aqueous phosphoric acid chromic acid solution which is prepared by dissolving 35 ml of 85% by weight phosphoric acid and 20 g of chromium (IV) oxide in 1 liter of water.

It is preferred that the anodized aluminum plate is treated with an aqueous sodium silicate solution at preferably from 20 to 50° C., and more preferably from 20 to 45° C. Although not specifically limited, the concentration of sodium silicate in the aqueous sodium silicate solution is preferably from 0.01 to 35% by weight, and more preferably from 0.1 to 5 by weight.

It is preferred that the anodized aluminum plate is preferably treated with an aqueous polyvinyl phosphonic acid solution at preferably from 20 to 70° C., and more preferably from 30 to 65° C. Although not specifically limited, the concentration of polyvinyl phosphonic acid in the aqueous polyvinyl phosphonic acid solution is preferably from 0.01 to 35% by weight, and more preferably from 0.1 to 5 by weight.

### (Imagewise Exposure)

As a light source for recording an image on the light sensitive planographic printing plate material of the invention, a laser having an emission wavelength of from 350 to 430 nm is preferably used.

Examples of such a laser include a He—Cd laser (441 nm), a combination of Cr:LiSAF and SHG crystals (430 nm) as a solid laser, and KnbO3, ring resonator (430 nm), AlGaInN (350-350 nm) or AlGaInN semiconductor laser (InGaN type semiconductor laser available on the market, 400-410 nm) as a semiconductor type laser.

When a laser is used for exposure, which can be condensed in the beam form, scanning exposure according to an image can be carried out, and direct writing is possible without using any mask material. When the laser is employed for imagewise exposure, a highly dissolved image can be obtained, since it is easy to condense its exposure spot in minute size.

As a laser scanning method of lasers used in the invention, there are a method of laser scanning on an outer surface of a cylinder, a method of laser scanning on an inner surface of a cylinder and a method of laser scanning on a plane. In the method of laser scanning on an outer surface of a cylinder, laser beam exposure is conducted while a drum around which a recording material is wound is rotated, in which main scanning is represented by the rotation of the drum, while sub-scanning is represented by the movement of the laser beam. In the method of laser scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of laser scanning on a plane, main scanning by means of a laser beam is carried out through a combination of a polygon mirror, a galvano mirror and an Fθ lens, and sub-scanning is carried out moving a recording medium. The cylinder outer surface laser scanning method and the cylinder inner surface laser scanning method are suitable for high density image recording, since it is easier to increase accuracy of an optical system. The cylinder outer surface laser scanning method is especially preferred in employing laser energy effectively, and in designing easily the optical system including the laser used.

In the invention, imagewise exposure is carried out at a plate surface energy (an exposure energy at the surface of the planographic printing plate material) of from 10 to 500 mJ/cm², and more preferably from 10 to 300 mJ/cm². This exposure energy can be measured, employing a laser power meter PDGDO-3W produced by Ophir Optronics Inc.

### (Preheating Treatment)

In the invention, the exposed planographic printing plate material is preferably subjected to heat treatment before or during development. Such a heat treatment can increase adhesion between a support and an image formation layer provided thereon, resulting in increase of printing durability.

Regarding pre-heating treatment, there is, for example, a developing machine in which a preheating roller for preheating an exposed planographic printing plate material to a predetermined temperature is arranged upstream a development section where the preheating is carried out before development. The preheating roller is a roller comprised of a pair of rollers, at least one of the pair of the rollers having a heating means within the roller. The roller having a heating means in it is a pipe of a metal with high thermal conductivity such as aluminum or iron, the pipe having a nichrome wire as a heating element. The outside surface of the pipe may be covered with a sheet of a plastic such as polyethylene, polystyrene or Teflon. Details of such a preheating roller can refer to Japanese Patent O.P.I. Publication No. 64-80962. In the invention, it is preferred that the preheating is carried out at 70 to 180° C. for 3 to 120 seconds.

### (Developer)

In the invention, the imagewise exposed image formation layer, which are cured are at exposed portions, is developed with an alkali developer, whereby the image formation layer at exposed portions are removed to form an image.

As the alkali developer, a conventional alkali aqueous solution is used. For example, there is an alkali developer containing an inorganic alkali agent such as sodium silicate, potassium silicate, ammonium silicate, sodium secondary phosphate, potassium secondary phosphate, ammonium secondary phosphate; sodium hydrogen carbonate, potassium hydrogen carbonate, ammonium hydrogen carbonate; sodium carbonate, potassium carbonate, ammonium carbonate; sodium borate, potassium borate, lithium borate; sodium hydroxide, potassium hydroxide, and ammonium hydroxide.

The alkali developer can contain organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, and pyridine.

These alkali agents can be used singly or as a mixture of two or more thereof. The alkali developer can contain an anionic surfactant, an amphoteric surfactant, or an organic solvent such as alcohol.

### (Surfactant)

Various surfactants or organic solvents can be optionally added to a developer used in the invention, in order to accelerate development, disperse smuts occurring during development, or enhance ink receptivity at the image portions of a printing plate.

As the surfactant, there are an anionic surfactant, a cationic surfactant, a nonionic surfactant, and an amphoteric surfactant. Preferred examples of the nonionic surfactant include polyoxyethylenealkyl ethers, polyoxyethylenealkylphenyl ethers, polyoxyethylene-polystyrylphenyl ethers, polyoxyethylenepolyoxypropylenalkyl ethers, partial esters of glycerin and fatty acids, partial esters of sorbitan and fatty acids, partial esters of pentaerythritol and fatty acids, propylene glycol monofatty acid ester, partial esters of sucrose and fatty acids, partial esters of polyoxyethylenesorbitan and fatty acids, partial esters of polyoxyethylenesorbitol and fatty acids, esters of polyoxyethylene glycol and fatty acids, partial esters of polyglycerin and fatty acids, polyoxyethylene castor oil, partial esters of polyoxyethyleneglycerin and fatty acids, polyoxyethylene-polyoxypropylene block copolymer, adduct of polyoxyethylene-polyoxypropylene block copolymer with ethylene imine, fatty acid diethanolamides, N,N-bis-2-hydroxyalkylamines, polyoxyethylenealkylamines, triethanolamine fatty acid esters, and trialkylamine oxides. Examples of the anionic surfactant include fatty acid salts, abietic acid salts, hydroxyalkane sulfonic acid salts, alkane sulfonic acid salts, dialkylsulfosuccinic acid salts, straight-chained alkylbenzene sulfonic acid salts, branched alkylbenzene sulfonic acid salts, alkylnaphthalene sulfonic acid salts, alkyldiphenylether sulfonic acid salts, alkylphenoxypolyoxyethylenepropyl sulfonic acid salts, polyoxyethylenealkyl sulfophenylether salts, N-methyl-N-oleiltaurine sodium salts, N-alkylsulfosuccinic acid monoamide disodium salts, petroleum sulfonic acid salts, nitrated castor oil, sulfated beef tallow, fatty acid alkyl ester sulfate salts, alkylsulfate salts, polyoxyethylenealkylethersulfate salts, fatty acid monoglyceride sulfate salts, polyoxyethylenealkylphenylethersulfate salts, polyoxyethylenestyrylphenylethersulfate salts, alkylphosphate salts, polyoxyethylenealkyletherphosphate salts, polyoxyethylenealkylphenyletherphosphate salts, partial saponification products of styrene-maleic anhydride copolymers, partial saponification products of olefin maleic anhydride copolymers, and condensates of naphthalene sulfonic acid salts with formalin. Examples of the cationic surfactant include alkylamine salts, quaternary ammonium salts such as tetrabutylammonium bromide, polyoxyethylene alkylamine salts, and polyethylene polyamine derivatives. Examples of the amphoteric surfactant include carboxybetains, aminn carboxylic acids, sulfobetaines, aminosulfates and imidazolines.

A more preferred surfactant is a fluorine-containing surfactant having a perfluoroalkyl group in the molecule. Examples thereof include anionic surfactants such as perfluoroalkylcarboxilic acid salts, or perfluoroalkylsurfuric acid salts, amphoteric surfactants such as perfluorobetaines, cationic surfactants such as perfluoroalkyltrimethylammonimum chlorides, and nonionic surfactants such as perfluoroalkylamineoxides, perfluoroalkylethyleneoxide adducts, oligomers having a perfluoroalkyl group and a hydrophilic group, oligomers having a perfluoroalkyl group and an oleophilic group, oligomers having a perfluoroalkyl group, a hydrophilic group, and an oleophilic group, and urethanes having a perfluoroalkyl group and an oleophilic group.

These surfactants can be used singly or as a mixture of two or more thereof. The developer preferably contains the surfactant in an amount of preferably from 0.001 to 10% by weight, and more preferably from 0.01 to 5% by weight.

### (Automatic Developing Machine)

The light sensitive planographic printing plate material is preferably developed through an automatic developing machine. It is preferred that a means for replenishing a developer replenisher in a necessary amount, a means for discharging any excessive developer, or a means for automatically replenishing water in necessary amounts is attached to the development section. It is preferred that the automatic developing machine comprises a means for detecting a transported planographic printing plate precursor, a means for calculating the area of the planographic printing plate precursor based on the detection, or a means for controlling the replenishing amount of a developer replenisher, the replenishing amount of water to be replenished, or the replenishing timing. It is also preferred that the automatic developing machine comprises a means for detecting a pH, temperature and/or electric conductivity of a developer, or a means for controlling the replenishing amount of the developer replenisher, the replenishing amount of water to be replenished or the replenishing timing, based on the detection. It is also preferred to provide a mechanism of diluting the developer concentrate with water and of stirring the diluted concentrate. Where the developing step is followed by a washing step, washing water used for washing can be reused as dilution water for diluting the developer concentrate.

The automatic developing machine used in the invention may be provided with a pre-processing section to allow the plate to be immersed in a pre-processing solution prior to development. The pre-processing section is provided preferably with a mechanism of spraying a pre-processing solution onto the plate surface, preferably with a mechanism of controlling the pre-processing solution at a temperature within the range of 25 to 55° C., and preferably with a mechanism of rubbing the plate surface with a roller-type brush. Common water and the like are employed as the pre-processing solution.

### (Post-processing)

The developed printing plate material is preferably subjected to post-processing. The post-processing step comprises post-processing the developed precursor with a post-processing solution such as washing water, a rinsing solution containing a surfactant, a finisher or a protective gumming solution containing gum arabic or starch derivatives as a main component. The post-processing step is carried out employing an appropriate combination of the post-processing solution described above. For example, a method is preferred in which a developed planographic printing plate precursor is post-washed with washing water, and then processed with a rinsing solution containing a surfactant, or a developed planographic printing plate precursor is post-washed with washing water, and then processed with a finisher, since it reduces fatigue of the rinsing solution or the finisher. It is preferred that a multi-step countercurrent processing is carried out employing a rinsing solution or a finisher.

The post-processing is carried out employing an automatic developing machine having a development section and a post-processing section. In the post-processing step, the developed printing plate is sprayed with the post-processing solution from a spray nozzle or is immersed into the post-processing solution in a post-processing tank. A method is known in which supplies a small amount of water onto the developed printing plate precursor to wash the precursor, and reuses the water used for washing as a dilution water for developer concentrate. In the automatic developing machine, a method is applied in which each processing solution is replenished with the respective processing replenisher according to the area of the printing plate precursor to have been processed or the operating time of the machine. A method (use-and-discard method) can be applied in which the developed printing plate material is processed with fresh processing solution and discarded. The thus obtained planographic printing plate is mounted on a printing press, and printing is carried out.

### (Gum Solution)

Gum solution may be suitably added with acids or buffers to remove from the developed plate alkaline ingredients which are contained in the developer. Further, there may be added a hydrophilic polymer compound, a chelating agent, a lubricant, an antiseptic and a solubilizing agent. Inclusion of the hydrophilic polymer compound in the gum solution provides a function as a protecting agent to prevent the developed plate from flawing or staining.

### (Washing Water Used Prior to Development)

Washing solution used in the washing stage prior to development invention is usually common water and may optionally be added with additives such as chelating agents, surfactants or antiseptics.

In washing, a washing solution used prior to development is used preferably at a controlled temperature, and more preferably at 10 to 60° C. Washing can be performed using commonly known solution-feeding techniques such as a spraying, dipping or coating method. During washing, a wash promoting method employing a brush, a squeezing roll or a submerged shower in a dipping treatment can be suitably used.

After completion of the washing stage prior to development, development may be immediately conducted, or drying may be conducted after the washing stage; subsequently, development may be performed. The development stage is followed by a post-treatment such as washing, rinsing or a gumming treatment. Washing water used prior to development may also be reused as washing water or for a rinsing solution or gumming solution.

### EXAMPLES

Next, the present invention will be explained below employing examples, but the present invention is not limited thereto. In the examples, “parts” represents “parts by weight”, unless otherwise specified.

### (Preparation of Polymeric Binder P-1)

Methyl methacrylate of 70.0 parts, 30.0 parts of methacrylic acid, 100 parts of ethanol, and 1.23 parts of α,α′-azobisisobutylonitrile were placed in a three neck flask under nitrogen atmosphere, and reacted under nitrogen atmosphere for 6 hours at 80° C. in an oil bath. Thus, polymeric binder P-1 was prepared. The polymeric binder P-1 had a weight average molecular weight of 30,000, measured according to GPC, and had an acid value of 190 and a Tg of 142° C.

### (Preparation of Polymeric Binders P-2 Through P-14)

The polymeric binders P-2 through P-14 were prepared in the same manner as above, except that kinds of monomers or the amount of the monomers used were changed as shown in Table 1. The weight average molecular weight, acid value and Tg of the resulting polymeric binders are shown in Table 1.

TABLE 1

| | Monomers used and their amount | | | | | | | | |
|---|---|---|---|---|---|---|---|---|---|
| Polymeric | (parts) | | | | | | Acid | Tg | |
| binder | MAA | MMA | EMA | AA | ACMO | 4-HSt | value | (° C.) | Mw |
| P-1 | 30 | 70 | — | — | — | — | 190 | 142 | 30,000 |
| P-2 | 20 | 80 | — | — | — | — | 130 | 130 | 30,000 |
| P-3 | 18 | 82 | — | — | — | — | 117 | 127 | 30,000 |
| P-4 | 14 | 86 | — | — | — | — | 91 | 122 | 30,000 |
| P-5 | 8 | 92 | — | — | — | — | 52 | 115 | 30,000 |
| P-6 | 6 | 94 | — | — | — | — | 33 | 111 | 30,000 |
| P-7 | 14 | — | 86 | — | — | — | 91 | 88 | 30,000 |
| P-8 | 14 | 30 | 56 | — | — | — | 91 | 100 | 30,000 |
| P-9 | 14 | 43 | — | 43 | — | — | 91 | 148 | 60,000 |
| P-10 | 14 | 43 | — | — | 43 | — | 91 | 140 | 60,000 |
| P-11 | 14 | 43 | — | — | — | 43 | 91 | 146 | 60,000 |
| P-12 | 14 | 66 | — | 20 | — | — | 91 | 134 | 30,000 |
| P-13 | 14 | 66 | — | — | 20 | — | 91 | 131 | 30,000 |
| P-14 | 14 | 66 | — | — | — | 20 | 91 | 133 | 30,000 |

MAA: Methacrylic acid;
MMA: Methyl methacrylate;
EMA: Ethyl methacrylate;
AA: Acrylamide;
ACMO: Morpholylacrylamide;
4-HSt: 4-Hydroxystyrene

The transition temperature Tg of a homopolymer of each of the monomers used herein is as follows:

| Homopolymer | Tg (° C.) |
|---|---|
| PMAA | 228 |
| PMMA | 105 |
| PEMA | 65 |
| PAA | 165 |
| PACMO | 147 |
| P(4-Hst) | 160 |

### Preparation of Planographic Printing Plate Material Sample

### (Preparation of Support)

A 0.30 mm thick aluminum plate (material 1050, refining H16) was degreased at 65° C. for one minute in a 5% sodium hydroxide solution, washed with water, immersed at 25° C. for one minute in a 10% sulfuric acid solution to neutralize, and then washed with water. The resulting aluminum plate was electrolytically etched using an alternating current at 25° C. for 20 seconds at a current density of 50 A/dm² and at a frequency of 50 Hz in an aqueous 11 g/liter hydrochloric acid solution, washed with water, desmutted at 50° C. for 10 seconds in a 1% sodium hydroxide solution, washed with water, neutralized at 50° C. for 30 seconds in a 30% sulfuric acid solution, and washed with water. The desmutted aluminum plate was anodized at 25° C. for 30 seconds at a current density of 30 A/dm² and at a voltage of 25 V in a 30% sulfuric acid solution, and washed with water. The resulting anodized aluminum plate was immersed in a 0.44% polyvinyl phosphonic acid aqueous solution at 750° C. for 30 seconds, washed with pure water, and dried blowing cool air. Thus, a support for a planographic printing plate material sample was obtained. The center line average surface roughness (Ra) of the support was 0.50 μm.

### Example 1

### (Preparation of Planographic Printing Plate Material Samples)

The following photopolymerizable light sensitive layer coating liquid was coated on the resulting support using an extrusion coater, dried at 60° C. for 20 seconds at a first drying step, and further dried at 100° C. for 60 seconds at a second drying step to form a light sensitive layer with a dry thickness of 1.5 g/m². After that, the following protective layer coating liquid was coated on the resulting light sensitive layer using a reverse roll coater, dried at 60° C. 20 seconds at a first drying step, and further dried at 100° C. for 60 seconds at a second drying step to form a protective layer with a dry thickness of 1.7 g/m². Thus, planographic printing plate material samples 1 through 14 as shown in Table 2 were prepared.

(Photopolymerizable light sensitive layer coating liquid)

| | | |
|---|---|---|
| Polymeric binder (as shown in Table 1) | 44.0 | parts |
| Sensitizing dye A | 6.0 | parts |
| Iron-arene compound IRGACURE 261 | 1.5 | parts |
| (produced by Ciba Specialty Chemicals Co.) | | |
| Triazine Compound TAZ-107 | 1.5 | parts |
| (produced by Midori Kagaku Co., Ltd.) | | |
| Ethylenically unsaturated compound PM-1 | 36 | parts |
| Ethylenically unsaturated compound 3G | 8 | parts |
| Phthalocyanine pigment | 3.0 | parts |
| (MHI 454 produced by Mikuni Sikisosha 30% MEK | | |
| dispersion) | | |
| Fluorine-contained surfactant | 0.1 | parts |
| (F-178K produced by Dainippon ink Kagaku Kogyo Co., | | |
| Ltd.) | | |
| ANCAMIN K-54 | 1.5 | parts |
| (produced by AIR PRODUCTS Co., Ltd.) | | |
| Cyclohexanone (bp. 155° C.) | 820 | parts |
| (Protective layer coating liquid) | | |
| Polyvinyl alcohol AL06 | 95 | parts |
| (produced by Nippon Gosei Kagaku Co., Ltd.) | | |
| Vinyl pyrrolidone copolymer VA64W | 5 | parts |
| (produced by BASF Co., Ltd.) | | |
| Surfactant Surfinol 465 | 0.5 | parts |
| (produced by Nisshin Kagaku Co., Ltd.) | | |
| Water | 900 | parts |

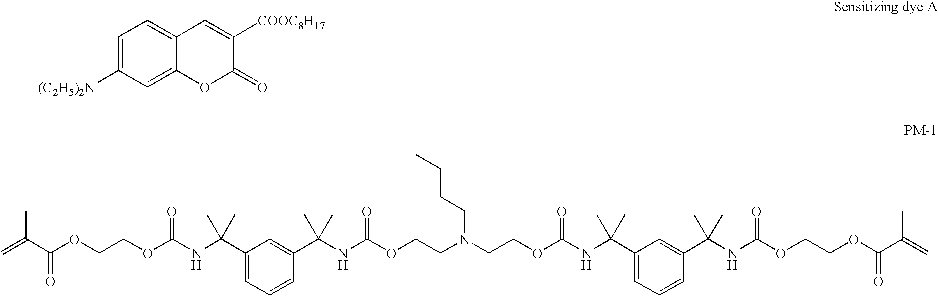

### (Image Formation)

The planographic printing plate material sample obtained above was imagewise exposed at a resolving degree of 2400 dpi, employing a modified plate setter of a plate setter Tiger Cat (produced by ECRM Co., Ltd.) equipped with a laser with an output power of 30 mW emitting light with a wavelength of 408 nm. Herein, dpi represents the dot numbers per 2.54 cm.

Subsequently, the exposed sample was subjected to development treatment employing a CTP automatic developing machine (PHW 32-V produced by Technigraph Co., Ltd.) to obtain a planographic printing plate. Herein, the developing machine comprised a preheating section for preheating the exposed sample, a pre-washing section for removing the protective layer before development, a development section charged with developer having the following developer composition, a washing section for removing the developer remaining on the developed sample after development, and a gumming section charged with a gumming solution (a solution obtained by diluting GW-3, produced by Mitsubishi Chemical Co., Ltd., with water by a factor of 2) for protecting the surface of the developed sample. Thus, planographic printing plate sample was obtained. Herein, preheating was carried out at 110° C. for 15 seconds, and development was carried out at 28° C. for 30 seconds. The preheating temperature was measured employing a thermo label (produced by Nichiyu Giken Co., Ltd.) adhered on the rear surface of the support opposite the light sensitive layer.

(Composition of developer)

| | |
|---|---|
| Potassium silicate A | 8.0 parts |
| (an aqueous potassium silicate solution containing | |
| 25.5–27.5% by weight of SiO₂ and | |
| 12.5–14.5% by weight of K₂O) | |
| NEWCOL B-13SN (produced | 3.0 parts |
| by Nippon Nyukazai Co., Ltd.) | |
| Disodium ethylenediaminetetraacetate dihydrate | 0.1 parts |
| Potassium hydroxide | Amount |
| | giving pH 12.45 |

### (Evaluation of planographic printing plate material sample)

The planographic printing plate material sample obtained above was evaluated as follows:

### <<Sensitivity>>

The light sensitive planographic printing plate material sample obtained above was exposed at various exposure energy levels of laser used to form solid images, and developed in the same manner as above to obtain developed solid images. Optical densities of the developed solid images were measured employing a densitometer D196manufactured by GRETAG Co. Ltd.

An exposure energy giving a reflection density of 90% of the maximum optical density of the developed solid image was defined as sensitivity (in terms of μm/cm²). The lower the exposure energy is, the higher the sensitivity.

### <<Storage stability>>

The planographic printing plate material sample was stored at 55° C. and at 20% RH for 3 days in a thermostatic chamber (DT storage). Sensitivity of the resulting sample was determined in the same manner as above as a measure of storage stability, and compared with that before storage.

### <<Anti-stain property>>

The planographic printing plate material sample after the storage was developed in the same manner as above to obtain a planographic printing plate, and printing was carried out employing the planographic printing plate under the following printing conditions to obtain 100 prints.

Stainings were observed at the non-image portions of the 100^{th} print, and anti-stain property was evaluated according to the following criteria.
A: No stain was observed at the non-image portions.
B: Apparent stain was observed at the non-image portion, which was unacceptable as a print.

### (Printing Conditions)

Printing Press: DAIYA1F-1 (produced by Mitsubishi Jukogyo Co., Ltd.)
Blanket: SR-100 (produced by SRI hybrid Co., Ltd.)
Printing Paper: Coat paper having a regenerated pulp content of 20% (produced by Hokuetsu Seishi Co., Ltd.)
Printing Ink: Soybean Oil Ink Naturalith 100 (Y, M, C, K (sumi ink)) (produced by Dainippon Ink Chemical Co., Ltd.)
Dampening Water: (SG-51, H solution, Concentration: 1.5% (produced by Tokyo Ink Co., Ltd.)
Printing Speed: 4000sheets per hour

### <<Printing Durability>>

The planographic printing plate material sample obtained above (before storage) was exposed at exposure amount of 80 μj/cm², employing an dot image chart with a 1 to 99% dot area of a screen line number of 175, and subjected to development treatment in the same manner as above, whereby a printing plate sample was obtained. Subsequently, printing was carried out employing the resulting printing plate sample under the same conditions as above, and the number of sheets printed until when the 3% dot area was changed to 0% or 6% dot area was determined and evaluated as a measure of printing durability.

### <<Pre-Heating Latitude>>

The planographic printing plate material sample obtained above (before storage) was exposed at exposure amount providing its sensitivity and subjected to development treatment in the same manner as above except that the preheating temperature was varied, whereby a printing plate sample was obtained. Subsequently, printing was carried out employing the resulting printing plate sample under the same conditions as above, and the maximum preheating temperature, at which neither stain at non-image portions nor filling-up at shadow image portions was produced, was determined.

In this evaluation, the pre-heating section of the automatic developing machine was switched off. The planographic printing plate material sample was pre-heated in a separate heater in a safe-light room to arrive at an intended temperature in 30 seconds.

The results are shown in Table 2.

TABLE 2

| | | | | | Pre- | Printing | |
|---|---|---|---|---|---|---|---|
| | Polymeric | | Storage | Anti- | Heating | Durability | |
| Sample | binder | Sensitivity | Stability | stain | Latitude | (Sheet | |
| No. | used | (μj/cm²) | (μj/cm²) | Property | (° C.) | Number) | Remarks |
| 1 | P-1 | 40 | 80 | A | 130 | 20,000 | Comp. |
| 2 | P-2 | 25 | 50 | A | 140 | 50,000 | Comp. |
| 3 | P-3 | 20 | 25 | A | 150 | 100,000 | Inv. |
| 4 | P-4 | 20 | 22 | A | 150 | 110,000 | Inv. |
| 5 | P-5 | 20 | 22 | A | 150 | 100,000 | Inv. |
| 6 | P-6 | 20 | 22 | B | 110 | — | Comp. |
| 7 | P-7 | 40 | 60 | A | 130 | 20,000 | Comp. |
| 8 | P-8 | 30 | 40 | A | 140 | 30,000 | Comp. |
| 9 | P-9 | 20 | 22 | A | 150 | 170,000 | Inv. |
| 10 | P-10 | 20 | 22 | A | 150 | 170,000 | Inv. |
| 11 | P-11 | 20 | 22 | A | 150 | 170,000 | Inv. |
| 12 | P-12 | 20 | 22 | A | 150 | 150,000 | Inv. |
| 13 | P-13 | 20 | 22 | A | 150 | 150,000 | Inv. |
| 14 | P-14 | 20 | 22 | A | 150 | 150,000 | Inv. |

Comp.: Comparative,
Inv.: Inventive

As is apparent from Table 2 above, inventive planographic printing plate material samples provide high sensitivity, high storage stability, high anti-stain property, good pre-heating latitude and high printing durability.

### Example 2

A planographic printing plate material sample 2′ was prepared in the same manner as in planographic printing plate material sample 2 of Example 1 above, except that LIGHT ESTER PE-3A (pentaerythritol triacrylate) produced by Kyoeisha Kagaku Co., Ltd. was used instead of ethylenically unsaturated compound PM-1 in the photopolymerizable light sensitive layer coating liquid. A planographic printing plate material sample 4′ was prepared in the same manner as in planographic printing plate material sample 4 of Example 1 above, except that LIGHT ESTER PE-3A (pentaerythritol triacrylate) produced by Kyoeisha Kagaku Co., Ltd. was used instead of ethylenically unsaturated compound PM-1 in the photopolymerizable light sensitive layer coating liquid.

The resulting samples 2′ and 4′ were processed and evaluated in the same manner as in Example 1. The results are shown in Table 3.

TABLE 3

| | | | | | Pre- | Printing | |
|---|---|---|---|---|---|---|---|
| | Polymeric | | Storage | Anti- | Heating | Durability | |
| Sample | binder | Sensitivity | Stability | stain | Latitude | (Sheet | |
| No. | used | (μj/cm²) | (μj/cm²) | Property | (° C.) | Number) | Remarks |
| 2′ | P-2 | 40 | * | B | 130 | 20,000 | Comp. |
| 4′ | P-4 | 27 | 30 | A | 140 | 50,000 | Inv. |

Comp.: Comparative,
Inv.: Inventive
* No image was formed.

As is apparent from Table 3, inventive planographic printing plate material sample 4′ provides high sensitivity, high storage stability, high anti-stain property, good pre-heating latitude and high printing durability, as compared to comparative planographic printing plate material sample 4′.

### Example 3

Each of planographic printing plate material samples 1 through 6 prepared in Example 1 was processed in the same manner as in Example 1, except that the preheating temperature was changed as shown in Table 4 and development was carried out at a developing speed of 114 cm/min (for 19 seconds), employing a CTP developing machine Raptor 85 Polymer produced by G & J Co., Ltd. Sensitivity in terms of μm/cm² of the sample processed at each pre-heating temperature was determined in the same manner as in Example 1. The results are shown in Table 4.

TABLE 4

| | | Sensitivity (μj/cm²) | | | | | |
|---|---|---|---|---|---|---|---|
| | Polymeric | at various pre-heating. | | | | | |
| | binder | temperatures | | | | | |
| Sample No. | used | 110° C. | 120° C. | 130° C. | 140° C. | 150° C. | Remarks |
| 1 | P-1 | 40 | 35 | 30 | * | * | Comp. |
| 2 | P-2 | 25 | 22 | 20 | 25 | * | Comp. |
| 3 | P-3 | 20 | 18 | 20 | 23 | 27 | Inv. |
| 4 | P-4 | 20 | 18 | 20 | 23 | 27 | Inv. |
| 5 | P-5 | 20 | 23 | 26 | 30 | 30 | Inv. |
| 6 | P-6 | 20 | * | * | * | * | Comp. |

Comp.: Comparative,
Inv.: Inventive
“*” means that stains wereobserved at non-image portions after development.

As is apparent from Table 4, inventive samples provide excellent pre-heating latitude, maintaining high sensitivity, as compared to comparative planographic printing plate material samples.

What is claimed is:

1. A light sensitive planographic printing plate material comprising a support and provided thereon, a light sensitive layer containing a polymeric binder, a polymerizable ethylenically unsaturated compound and a photopolymerization initiator, wherein the polymeric binder is a polymer having an acid value of from 40 to 120 and a glass transition temperature Tg of from 105 to 200° C.

2. The light sensitive planographic printing plate material of claim 1, wherein said polymer has an acid value of from 60 to 110 and a glass transition temperature Tg of from 110 to 180° C.

3. The light sensitive planographic printing plate material of claim 1, wherein said polymer is a copolymer containing two or more kinds of monomer units, the glass transition temperature of a homopolymer consisting of one of the monomer units constituting the copolymer being not less than 105° C.

4. The light sensitive planographic printing plate material of claim 3, wherein the copolymer comprises a (meth)acrylic acid monomer unit in the molecule.

5. The light sensitive planographic printing plate material of claim 1, wherein the polymerizable ethylenically unsaturated compound has both amide bond and a secondary or tertiary amino group in the molecule.

6. The light sensitive planographic printing plate material of claim 1, wherein the photopolymerization initiator is selected from the group consisting of a polyhalogenated compound, a biimidazole compound and an iron arene complex.

7. The light sensitive planographic printing plate material of claim 6, wherein the photopolymerization initiator is a combination of a polyhalogenated compound and an iron arene complex.

8. The light sensitive planographic printing plate material of claim 1, wherein the content of the polymeric binder in the light sensitive layer is from 10 to 90% by weight, based on the total weight of the light sensitive layer, the content of the polymerizable ethylenically unsaturated compound in the light sensitive layer is from 1.0 to 80% by weight, based on the total weight of the light sensitive layer, and the content of the photopolymerization initiator in the light sensitive layer is from 0.1 to 20% by weight, based on the weight of the polymerizable ethylenically unsaturated compound contained in the light sensitive layer.

9. The light sensitive planographic printing plate material of claim 8, wherein the content ratio by weight of the polymerizable ethylenically unsaturated compound to the polymeric binder in the light sensitive layer is from 0.5 to 2.2.

10. The light sensitive planographic printing plate material of claim 1, wherein the light sensitive layer further contains an organic amine.

11. The light sensitive planographic printing plate material of claim 10, wherein the organic amine content of the light sensitive layer is from 0.1 to 20% by weight.

12. The light sensitive planographic printing plate material of claim 10, wherein the organic amine is represented by formula (I), 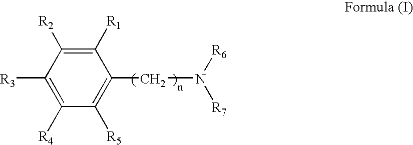
wherein n represents an integer of from 1 to 10; R₁ through R₅ independently represent a hydrogen atom, a halogen atom, a hydroxyl group, a formyl group, a carboxyl group, a cyano group, a nitro group, a sulfo group, a substituted or unsubstituted alkyl group, a substituted or unsubstituted alkenyl group, a substituted or unsubstituted aryl group, a substituted or unsubstituted aromatic heterocyclic group, a substituted or unsubstituted alkoxy group, a substituted or unsubstituted aryloxy group, a substituted or unsubstituted acyl group, a substituted or unsubstituted alkoxycarbonyl group, a substituted or unsubstituted acryloyloxy group, a substituted or unsubstituted alkylcarbonyloxy group, a substituted or unsubstituted alkylthio group, a substituted or unsubstituted sulfonyl group, a substituted or unsubstituted arylthio group, a substituted or unsubstituted amino group or a substituted or unsubstituted amido group; and R₆ and R₇ independently represent a hydrogen atom, a substituted or unsubstituted alkyl group, a substituted or unsubstituted alkenyl group, a substituted or unsubstituted aryl group, a substituted or unsubstituted aromatic heterocyclic group, or a substituted or unsubstituted aryloxy group.

13. A process for manufacturing a planographic printing plate from the light sensitive planographic printing plate material of claim 1, the process comprising the steps of:
(a) imagewise exposing the light sensitive planographic printing plate material;
(b) pre-heating the resulting imagewise exposed planographic printing plate material at a temperature of less than Tg of the polymeric binder; and
(c) developing the pre-heated planographic printing plate material, whereby a planographic printing plate is obtained.
